(19) United States
(12) Patent Application Publication
(10) Pub. No.: US 2023/0331922 A1
(43) Pub. Date: Oct. 19, 2023

(54) COMPOSITION, LIGHT SHIELDING FILM, SOLID-STATE IMAGING ELEMENT, IMAGE DISPLAY DEVICE, AND METHOD FOR MANUFACTURING CURED FILM

(71) Applicant: FUJIFILM Corporation, Tokyo (JP)

(72) Inventors: Hiroaki IDEI, Shizuoka (JP); Teppei Abe, Shizuoka (JP); Yoshinori Taguchi, Shizuoka (JP)

(73) Assignee: FUJIFILM Corporation, Tokyo (JP)

(21) Appl. No.: 18/176,479

(22) Filed: Mar. 1, 2023

(30) Foreign Application Priority Data
Mar. 4, 2022 (JP) 2022-033415

(51) Int. Cl. C08G 77/445; C08K 13/02

(52) U.S. Cl. CPC C08G 77/445; C08K 13/02

(57) ABSTRACT

Provided are a composition with which a cured film having excellent light shielding properties and small change in reflectivity before and after a heat resistance test can be produced; a light shielding film; a solid-state imaging element; an image display device; and a method for manufacturing a cured film.

The composition includes carbon black, silica, barium sulfate, a polymerizable compound, and a polymerization initiator.

### CROSS-REFERENCE TO RELATED APPLICATIONS

The present application claims priority under 35 U.S.C. § 119 to Japanese Patent Application No. 2022-033415, filed on Mar. 4, 2022. The above application is hereby expressly incorporated by reference, in its entirety, into the present application.

### BACKGROUND OF THE INVENTION

### 1. Field of the Invention

The present invention relates to a composition, a light shielding film, a solid-state imaging element, an image display device, and a method for manufacturing a cured film.

### 2. Description of the Related Art

A composition including black powder has been used for various purposes in the related art, and for example, the composition is used in the production of a light shielding film to be disposed in a liquid crystal display device and a solid-state imaging device such as a charge coupled device (CCD) image sensor and a complementary metal-oxide semiconductor (CMOS) image sensor. For example, a color filter used in the liquid crystal display device includes a light shielding film which is called a black matrix, for the purpose of shielding colored pixels from light, enhancing contrast, and the like. In addition, the solid-state imaging element is also provided with a light shielding film at a predetermined position for the purpose of preventing generation of noise, improving image quality, and the like.

For example, JP2019-082533A discloses, as a pigment dispersion resist composition for a black matrix with good light shielding properties and low reflectivity, a “pigment dispersion composition for a black matrix, including carbon black, precipitated barium sulfate, a basic group-containing pigment dispersing agent, a pigment derivative, an alkali-soluble resin, and a solvent, characterized in that a content ratio of the carbon black and the precipitated barium sulfate (carbon black/precipitated barium sulfate) is 95/5 to 65/35”.

### SUMMARY OF THE INVENTION

In a case where the present inventors have studied on a cured film formed of the composition disclosed in JP2019-082533A, it has been found that, although light shielding properties are good, reflectivity of the cured film changes before and after a heat resistance test in which the cured film is subjected to a heating treatment, and further improvement is required.

Therefore, an object of the present invention is to provide a composition with which a cured film having excellent light shielding properties and small change in reflectivity before and after a heat resistance test can be produced.

Another object of the present invention is to provide a light shielding film, a solid-state imaging element, an image display device, and a method for manufacturing a cured film.

As a result of conducting an extensive investigation to achieve the objects, the present inventors have found that the objects can be achieved by the following constitution.
(1) A composition comprising:
   carbon black;
   silica;
   barium sulfate;
   a polymerizable compound; and
   a polymerization initiator.
(2) The composition according to (1),
   in which the polymerizable compound includes a first polymerizable compound having 7 or more polymerizable groups.
(3) The composition according to (2),
   in which the polymerizable compound includes a second polymerizable compound having 6 or less polymerizable groups, and
   a mass ratio of a content of the second polymerizable compound to a content of the first polymerizable compound is 30/70 to 95/5.
(4) The composition according to (3),
   in which all of the polymerizable groups included in the first polymerizable compound and the polymerizable groups included in the second polymerizable compound are an acryloyl group or a methacryloyl group.
(5) The composition according to any one of (1) to (4),
   in which the polymerization initiator includes a compound represented by Formula (1) described later.
(6) The composition according to any one of (1) to (5), further comprising:
   one or more kinds of metal-containing particles selected from the group consisting of a metal nitride and a metal oxynitride.
(7) The composition according to any one of (1) to (5),
   in which, in a case where the composition does not include one or more kinds of metal-containing particles selected from the group consisting of a metal nitride and a metal oxynitride, a content of the carbon black is 10% to 55% by mass with respect to a total solid content of the composition, and
   in a case where the composition includes one or more kinds of metal-containing particles selected from the group consisting of a metal nitride and a metal oxynitride, a total content of the carbon black and the metal-containing particles is 10% to 55% by mass with respect to the total solid content of the composition.
(8) The composition according to any one of (1) to (7),
   in which an average particle diameter of the silica is 3 to 200 nm.
(9) The composition according to any one of (1) to (8),
   in which an average particle diameter of the barium sulfate is 3 to 200 nm.
(10) The composition according to any one of (1) to (9), further comprising:
   a silicone-based surfactant.
(11) The composition according to (10),
   in which the silicone-based surfactant is a surfactant having a phenyl group.
(12) The composition according to any one of (1) to (11), further comprising:
   copper phthalocyanines selected from the group consisting of copper phthalocyanine and a copper phthalocyanine derivative.
(13) The composition according to (12),
   in which the copper phthalocyanine derivative is a salt composed of copper phthalocyanine having a sulfonic acid group and dimethyldioctadecylammonium.
(14) The composition according to (12) or (13),
   in which a mass ratio of a content of the carbon black to a total content of the copper phthalocyanines is 4.0 to 99.
(15) The composition according to any one of (1) to (14),
   in which a mass ratio of a content of the carbon black to a content of the silica is 3.0 to 99.
(16) The composition according to any one of (1) to (15),
   in which a mass ratio of a content of the carbon black to a content of the barium sulfate is 1.5 to 99.
(17) The composition according to any one of (1) to (16),
   in which a mass ratio of a content of the barium sulfate to a content of the silica is 0.25 to 4.0.
(18) The composition according to any one of (1) to (17),
   in which a content of a solid content of the composition is 10% to 45% by mass with respect to a total mass of the composition.
(19) The composition according to any one of (1) to (18),
   in which the composition is a composition for forming a light shielding film.
(20) A light shielding film comprising:
   a cured film formed from the composition according to any one of (1) to (19).
(21) A solid-state imaging element comprising:
   a cured film formed from the composition according to any one of (1) to (19).
(22) An image display device comprising:
   a cured film formed from the composition according to any one of (1) to (19).
(23) A method for manufacturing a cured film, comprising:
   a composition layer forming step of forming a composition layer using the composition according to any one of (1) to (19) on a support;
   an exposure step of exposing the composition layer by irradiating the composition layer with an actinic ray or a radiation; and
   a development step of performing a development treatment on the composition layer after the exposure.
(24) The composition according to any one of (1) to (19), further comprising:
   an alkali-soluble resin,
   in which the alkali-soluble resin includes a repeating unit represented by Formula (A) described later and a repeating unit represented by Formula (B) described later, and
   a content of the repeating unit represented by Formula (A) is 30% by mass or more with respect to all repeating units included in the alkali-soluble resin.

According to the present invention, it is possible to provide a composition with which a cured film having excellent light shielding properties and small change in reflectivity before and after a heat resistance test can be produced.

In addition, according to the present invention, it is possible to provide a light shielding film, a solid-state imaging element, an image display device, and a method for manufacturing a cured film.

### DESCRIPTION OF THE PREFERRED EMBODIMENTS

Hereinafter, the present invention will be described in detail.

The description of the following configuration requirements is made based on typical embodiments of the present invention in some cases, but the present invention is not limited to the embodiments.

Furthermore, in the present specification, a numerical range expressed using “to” means a range including numerical values described before and after “to” as a lower limit value and an upper limit value.

In the present specification, regarding the description of a group (atomic group), in a case where whether the group is substituted or unsubstituted is not described, the group includes a group which has a substituent as well as a group which does not have a substituent. For example, an “alkyl group” includes not only an alkyl group (unsubstituted alkyl group) which does not have a substituent but also an alkyl group (substituted alkyl group) which has a substituent.

In addition, in the present specification, “actinic rays” or “radiations” refers to, for example, far ultraviolet rays, extreme ultraviolet rays (EUV: extreme ultraviolet lithography), X-rays, electron beams, and the like. In addition, in the present specification, light refers to actinic rays and radiations. In the present specification, unless otherwise specified, “exposure” includes not only exposure with far ultraviolet rays, X-rays, EUV light, or the like but also drawing by particle beams such as electron beams and ion beams.

In the present specification, “(meth)acrylate” represents acrylate and methacrylate. In the present specification, “(meth)acryl” represents acryl and methacryl. In the present specification, “(meth)acryloyl” represents acryloyl and methacryloyl. In the present specification, “(meth)acrylamide” represents acrylamide and methacrylamide. In the present specification, a “monomeric substance” and a “monomer” have the same definition.

In the present specification, a weight-average molecular weight (Mw) is a value in terms of polystyrene, as measured by a gel permeation chromatography (GPC) method.

In the present specification, the GPC method is based on a method in which HLC-8020 GPC (manufactured by TOSOH CORPORATION) is used, TSKgel SuperHZM-H, TSKgel SuperHZ4000, and TSKgel SuperHZ2000 (manufactured by TOSOH CORPORATION, 4.6 mm ID × 15 cm) are used as columns, and tetrahydrofuran (THF) is used as an eluent.

In the present specification, a solid content in a composition means a component which can constitute a cured film formed of the composition, and in a case where the composition includes a solvent, the solid content means all components except the solvent.

In addition, in a case where a component can constitute the cured film, the component which is a liquid component is also regarded as a solid content.

### Composition

The composition according to the embodiment of the present invention includes carbon black, barium sulfate, silica, a polymerizable compound, and a polymerization initiator.

A cured film formed of the composition according to the embodiment of the present invention has excellent light shielding properties (high minimum OD value at a wavelength of 400 to 1000 nm) and small change in reflectivity before and after a heat resistance test. A mechanism having the effects of the present invention due to the composition having the above-described configuration is not always clear, but is presumed to be as follows by the present inventors.

In a case where a cured film formed of a composition in the related art is subjected to the heat resistance test, it is presumed that a matrix around the carbon black changes due to thermal energy absorbed by carbon black in the cured film. It is considered that such a change in matrix impairs an uneven structure of a film surface before the heat resistance test, and changes the reflectivity.

As compared with the above-described composition in the related art, since the composition according to the embodiment of the present invention includes silica which functions as a binder, the cured film to be obtained is a firm film having a pseudo-crosslinking structure. Therefore, it is presumed that the above-described change in matrix is suppressed and the change in reflectivity of the cured film before and after the heat resistance test is small.

Moreover, since the composition according to the embodiment of the present invention mainly includes the carbon black, excellent light shielding properties are exhibited.

Hereinafter, at least one effect of the fact that the light shielding properties of the cured film formed of the composition according to the embodiment of the present invention are more excellent, that the reflectivity of the cured film formed of the composition according to the embodiment of the present invention is lower, viscosity stability over time of the composition according to the embodiment of the present invention is more excellent, that the change in reflectivity of the cured film formed of the composition according to the embodiment of the present invention after the heat resistance test is smaller, or that scratch resistance of the cured film formed of the composition according to the embodiment of the present invention is more excellent is referred to as that “the effect of the present invention is more excellent”.

Hereinafter, respective components included in the composition according to the embodiment of the present invention will be described in detail.

### Carbon Black

The composition according to the embodiment of the present invention includes carbon black.

The carbon black may be neutral, acidic, or basic.

An average primary particle diameter of the carbon black is preferably 10 to 60 nm, and from the viewpoint that the effect of the present invention is more excellent, more preferably 10 to 30 nm.

Examples of the acidic carbon black include those having a pH of less than 6.5. The pH of the acidic carbon black is preferably 2.0 to 6.0 and more preferably 2.0 to 4.0.

Specific examples of the acidic carbon black include Raven1080 (average primary particle diameter: 28 nm, pH: 2.4) and Raven1100 (average primary particle diameter: 32 nm, pH: 2.9) manufactured by Columbia Chemical; MA8 (average primary particle diameter: 24 nm, pH: 3.0), MA100 (average primary particle diameter: 24 nm, pH: 3.5), MA7 (average primary particle diameter: 24 nm, pH: 3.0), MA77 (average primary particle diameter: 23 nm, pH: 2.5), MA220 (average primary particle diameter: 55 nm, pH: 3.0), #2350 (average primary particle diameter: 15 nm, pH: 2.5, manufactured by Mitsubishi Chemical Corporation) manufactured by Mitsubishi Chemical Corporation; and SPECIAL BLACK 250 (average primary particle diameter: 56 nm, pH: 3.0), SPECIAL BLACK 350 (average primary particle diameter: 31 nm, pH: 3.0), SPECIAL BLACK 550 (average primary particle diameter: 25 nm, pH: 4), NEROX2500 (average primary particle diameter: 56 nm, pH: 3.0), and NEROX 3500 (average primary particle diameter: 31 nm, pH: 3.0) manufactured by Orion Engineered Carbons S.A.

Examples of the neutral and basic carbon black include those having a pH of 6.5 or more.

Specific examples of the neutral and basic carbon black include PRINTEX 25 (average primary particle diameter: 56 nm, pH: 9.5), PRINTEX 35 (average primary particle diameter: 31 nm, pH: 9.5), PRINTEX 45 (average primary particle diameter: 26 nm, pH: 9.5), and PRINTEX 65 (average primary particle diameter: 21 nm, pH: 9.5) manufactured by Orion Engineered Carbons S.A.; and #30 (average primary particle diameter: 30 nm, pH: 8.0) and #2600 (average primary particle diameter: 13 nm, pH: 6.5) manufactured by Mitsubishi Chemical Corporation.

The pH of the carbon black is a catalog value, or is a value obtained by the following measuring method X in a case where there is no catalog value.

measuring method X: 1 g of carbon black which is an object to be measured is added to 20 ml of distilled water (pH: 7.0) from which carbonic acid has been removed, the obtained aqueous solution is mixed with a magnetic stirrer to prepare an aqueous suspension, and using a glass electrode, pH of the obtained aqueous suspension is measured at 25° C. and the measured value is defined as the pH of the carbon black (Deutsche Industrie Norm DIN ISO 787/9).

The above-described average primary particle diameter of the carbon black is a catalog value, or is a value of an arithmetic mean diameter by electron microscope observation in a case where there is no catalog value.

A content of the carbon black in the composition according to the embodiment of the present invention is not particularly limited, but in a case where the composition according to the embodiment of the present invention does not include metal-containing particles described later, from the viewpoint that the effect of the present invention is more excellent, the content is preferably 10% to 55% by mass, more preferably 30% to 50% by mass, and still more preferably 40% to 50% by mass with respect to the total solid content of the composition.

The carbon black may be used alone or in combination of two or more kinds thereof. In a case where two or more kinds of the carbon blacks are used in combination, the total content thereof is preferably within the above-described range.

In addition, the composition according to the embodiment of the present invention may include metal-containing particles described later.

In a case where the composition according to the embodiment of the present invention includes metal-containing particles described later, the total content of the carbon black and the metal-containing particles is not particularly limited, but is preferably 10% to 55% by mass, more preferably 30% to 50% by mass, and still more preferably 40% to 50% by mass with respect to the total solid content of the composition.

### Silica

The composition according to the embodiment of the present invention includes silica.

The silica is preferably granular. An average particle diameter of the silica is not particularly limited, but is preferably 3 to 200 nm, more preferably 5 to 100 nm, and still more preferably 10 to 50 nm. Within the above-described range, the change in reflectivity of the cured film before and after the heat resistance test can be smaller.

The above-described average particle diameter of the silica is a catalog value, or a value measured by a BET method in a case where there is no catalog value.

A surface of the silica may be surface-treated. Examples of the surface treatment include a physical surface treatment such as a plasma discharge treatment and a corona discharge treatment, and a chemical surface treatment with a surfactant, a coupling agent, or the like.

The silica may be porous, hollow, or solid.

As the silica, a commercially available product or a synthetic product may be used.

Examples of a commercially available product as a raw material for the silica include colloidal silica (dispersion liquid in which granular silica is dispersed in a solvent) and dry silica.

Examples of the above-described commercially available product include “MA-ST-M”, “MA-ST-L”, “IPA-ST”, “IPA-ST-L”, “IPA-ST-ZL”, “IPA-ST-UP”, “EG-ST”, “NPC-ST-30”, “PGM-ST”, “DMAC-ST”, “MEK-ST-40”, “MEK-ST-L”, “MEK-ST-ZL”, “MEK-ST-UP”, “MIBK-ST”, “MIBK-ST-L”, “CHO-ST-M”, “EAT-ST”, “PMA-ST”, “TOL-ST”, “MEK-AC-2140Z”, “MEK-AC-4130Y”, “MEK-AC-5140Z”, “MIBK-AC-2140Z”, “MIBK-SD-L”, “PGM-AC-2140Y”, “PGM-AC-4140Y”, and “MEK-EC-2130Y” manufactured by Nissan Chemical Corporation; “Seahostar KE-E10”, “Seahostar KE-E30”, “Seahostar KE-E150”, “Seahostar KE-W10”, “Seahostar KE-W30”, “Seahostar KE-W50”, “Seahostar KE-P10”, “Seahostar KE-P30”, “Seahostar KE-P50”, “Seahostar KE-P100”, “Seahostar KE-P150”, “Seahostar KE-P250”, “Seahostar KE-S10”, “Seahostar KE-S30”, “Seahostar KE-S50”, “Seahostar KE-S100”, “Seahostar KE-S150”, and “Seahostar KE-S250” manufactured by NIPPON SHOKUBAI CO., LTD.; “QSG-10”, “QSG-30”, “QSG-100”, and “QSG-170” manufactured by Shin-Etsu Chemical Co., Ltd.; “ADMANANO YA010C”, “YA050C”, and “YA100C” manufactured by Admatechs.; and “DLSB-001” and “DLSB-002” manufactured by DAIKEN CHEMICAL.

A content of the silica in the composition according to the embodiment of the present invention is not particularly limited, but from the viewpoint that the effect of the present invention is more excellent, the content is preferably 0.1% by mass or more, more preferably 1.5% by mass or more, and still more preferably 3% by mass or more with respect to the total solid content of the composition. Moreover, the upper limit value thereof is preferably 25% by mass or less, more preferably 15% by mass or less, and still more preferably 10% by mass or less.

The silica may be used alone or in combination of two or more thereof. In a case where two or more silicas are used in combination, the total content thereof is preferably within the above-described range.

In addition, a mass ratio of the content of the carbon black to the content of the silica is not particularly limited and is usually 1.0 to 400, but from the viewpoint that the effect of the present invention is more excellent, the mass ratio is preferably 3.0 to 99 and more preferably 4.0 to 30.

### Barium Sulfate

The composition according to the embodiment of the present invention includes barium sulfate.

Examples of a suitable aspect of the barium sulfate include a precipitated barium sulfate.

From the viewpoint that the effect of the present invention is more excellent, an average particle diameter of the barium sulfate is preferably 3 to 200 nm and more preferably 3 to 100 nm.

Examples of a commercially available product of the barium sulfate include BF-20, BF-10, BF-21, BF-1, and BF-40 (all manufactured by SAKAI CHEMICAL INDUSTRY CO., LTD.).

A content of the barium sulfate in the composition according to the embodiment of the present invention is not particularly limited, but from the viewpoint that the effect of the present invention is more excellent, the content is preferably 0.5% by mass or more, more preferably 1.0% by mass or more, and still more preferably 2.0% by mass or more with respect to the total solid content of the composition. Moreover, the upper limit value thereof is preferably 15% by mass or less, more preferably 12% by mass or less, and still more preferably 5% by mass or less.

The barium sulfate may be used alone or in combination of two or more thereof. In a case where two or more kinds of barium sulfate are used in combination, the total content thereof is preferably within the above-described range.

In addition, a mass ratio of the content of the carbon black to the content of the barium sulfate is not particularly limited, but from the viewpoint that the effect of the present invention is more excellent, the mass ratio is preferably 1.5 to 99 and more preferably 3 to 40.

Moreover, a mass ratio of the content of the barium sulfate to the content of the silica is not particularly limited, but from the viewpoint that the effect of the present invention is more excellent, the mass ratio is preferably 0.1 to 10 and more preferably 0.25 to 4.0.

### Polymerizable Compound

The composition according to the embodiment of the present invention includes a polymerizable compound (compound having a polymerizable group).

In the present specification, the polymerizable compound means a compound which is polymerized by the action of the polymerization initiator which will be described later, and is intended to be different component from the resin and the epoxy group-containing compound described later.

The polymerizable compound is preferably a compound having an unsaturated double bond.

Specifically, the compound having an unsaturated double bond is preferably a compound having a group including an ethylenically unsaturated bond (hereinafter, also simply referred to as an “ethylenically unsaturated group”).

The polymerizable compound is preferably a compound having one or more polymerizable groups, more preferably a compound having two or more polymerizable groups (so-called polyfunctional polymerizable compound), and from the viewpoint that the effect of the present invention is more excellent, still more preferably a compound having three or more polymerizable groups, and particularly preferably a compound having four or more polymerizable groups. The upper limit of the number of polymerizable groups included in the polymerizable compound is not particularly limited, but is preferably 25 or less and more preferably 20 or less.

The polymerizable group is preferably an ethylenically unsaturated group. Examples of the ethylenically unsaturated group include a vinyl group, a (meth)allyl group, and a (meth)acryloyl group, and a (meth)acryloyl group is preferable.

The polymerizable compound may have an acid group such as a carboxylic acid group, a sulfonic acid group, and a phosphoric acid group.

Among them, the polymerizable compound is preferably an ester of an aliphatic polyhydroxy compound and an unsaturated carboxylic acid, more preferably a polymerizable compound obtained by reacting a nonaromatic carboxylic acid anhydride with an unreacted hydroxyl group of an aliphatic polyhydroxy compound, and still more preferably a compound in which the aliphatic polyhydroxy compound in the ester is pentaerythritol and/or dipentaerythritol. Examples of a commercially available product thereof include ARONIX TO-2349, M-305, M-309, M-510, and M-520 manufactured by TOAGOSEI CO., LTD.

An acid value of the polymerizable compound is preferably 0.1 to 40 mgKOH/g and more preferably 5 to 30 mgKOH/g. In a case where the acid value of the polymerizable compound is 0.1 mgKOH/g or more, development dissolution characteristics are favorable, and in a case where the acid value is 40 mgKOH/g or less, the polymerizable compound is advantageous in terms of production and/or handling. In addition, a photopolymerization performance is favorable, and curing properties of the composition according to the embodiment of the present invention are excellent.

### First Polymerizable Compound

From the viewpoint that the effect of the present invention is more excellent, the polymerizable compound preferably includes a first polymerizable compound having 7 or more polymerizable groups. In a case where the polymerizable compound includes the first polymerizable compound, the cured film formed of the composition according to the embodiment of the present invention has a very high crosslinking density, and as a result, the scratch resistance of the cured film can be good.

The first polymerizable compound may have 7 or more polymerizable groups, and from the viewpoint that the effect of the present invention is more excellent, the number of polymerizable groups included in the first polymerizable compound is preferably 7 to 30 and more preferably 9 to 20.

The type of the polymerizable group included in the first polymerizable compound is as described above.

The first polymerizable compound is preferably a compound represented by Formula (A-1) or Formula (A-2).

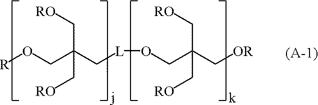

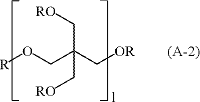

In Formula (A-1), L represents a divalent linking group.

The type of the divalent linking group is not particularly limited, and examples thereof include a divalent hydrocarbon group (which may be a divalent saturated hydrocarbon group or a divalent aromatic hydrocarbon group; the divalent saturated hydrocarbon group may be any of linear forms, branched forms, or cyclic forms, and preferably has 1 to 10 carbon atoms, and examples thereof include an alkylene group; the divalent aromatic hydrocarbon group preferably has 5 to 10 carbon atoms, and examples thereof include a phenylene group; other than these groups, the divalent hydrocarbon group may be an alkenylene group or an alkynylene group), a divalent heterocyclic group, —O—, —S—, —SO₂—, —NR^{A}—, —CO—(—C(═O)—), —COO—(—C(═O)O—), —NR^{A}—CO—, —SO₃—, —SO₂NR^{A}—, and a group of a combination of two or more kinds thereof. Here, R^{A} represents a hydrogen atom or an alkyl group (preferably having 1 to 10 carbon atoms). Among them, L is preferably —COO— divalent hydrocarbon group-, and more preferably —COO—alkylene group (preferably having 1 to 3 carbon atoms)-. In addition, in Formula (A-1), R represents a hydrogen atom or a (meth)acryloyl group.

j and k each independently represent an integer of 1 to 4, and the total number of j and k represents an integer of 3 or more. The total number of j and k is preferably an integer of 3 to 6, and more preferably 4.

Moreover, in Formula (A-1), 7 or more of (2 + 2j + 2k) pieces of R’s represent a (meth)acryloyl group. Among them, it is preferable that all R in Formula (A-1) are (meth)acryloyl groups.

In Formula (A-2), R represents a hydrogen atom or a (meth)acryloyl group.

1 represents an integer of 3 to 8. Among them, 1 is preferably 3 or 4.

Moreover, in Formula (A-2), 7 or more of (2 + 21) pieces of R’s represent a (meth)acryloyl group. Among them, it is preferable that all R in Formula (A-2) are (meth)acryloyl groups.

Specific examples of the first polymerizable compound include CN2302, CN2304, CN8885, and CN9013 (manufactured by Sartomer), TPOA-50 (manufactured by Shin-Nakamura Chemical Co., Ltd.), and UA-306H (manufactured by KYOEISHA CHEMICAL Co., LTD.).

VISCOAT #802 includes the first polymerizable compound and a second polymerizable compound described below.

### Second Polymerizable Compound

The polymerizable compound may include a second polymerizable compound having 6 or less polymerizable groups. In a case where the polymerizable compound includes the second polymerizable compound, the scratch resistance of the cured film formed of the composition according to the embodiment of the present invention is more excellent.

It is preferable that the polymerizable compound includes both the first polymerizable compound and the second polymerizable compound.

The second polymerizable compound may have 6 or less polymerizable groups, and from the viewpoint that the effect of the present invention is more excellent, the number of polymerizable groups included in the second polymerizable compound is preferably 1 to 6 and more preferably 3 to 6.

The type of the polymerizable group included in the second polymerizable compound is as described above.

Examples of a suitable aspect of the second polymerizable compound include a compound having a caprolactone structure.

The compound having a caprolactone structure is a compound including a caprolactone structure in the molecule, and examples thereof include ε-caprolactone-modified polyfunctional (meth)acrylate which is obtained by esterifying polyhydric alcohol such as trimethylolethane, ditrimethylolethane, trimethylolpropane, ditrimethylolpropane, pentaerythritol, dipentaerythritol, tripentaerythritol, glycerin, diglycerol, and trimethylol melamine, (meth)acrylic acid, and ε-caprolactone.

Among them, a compound which has a caprolactone structure and is represented by Formula (Z-1) is preferable.

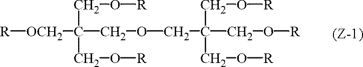

In Formula (Z-1), all six R’s are groups represented by Formula (Z-2), or one to five among the six R’s are groups represented by Formula (Z-2) and the others are groups represented by Formula (Z-3).

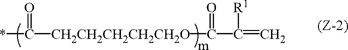

In Formula (Z-2), R¹ represents a hydrogen atom or a methyl group, m represents a number of 1 or 2, and “*” represents a bonding position.

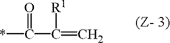

In Formula (Z-3), R¹ represents a hydrogen atom or a methyl group and “*” represents a bonding position.

As a commercially available product thereof, for example, KAYARAD DPCA series from Nippon Kayaku Co., Ltd. are available, and examples thereof include DPCA-20 (a compound in which m in Formulae (Z-1) to (Z-3) is 1, the number of groups represented by Formula (Z-2) is 2, and all of R^{1′}s represent hydrogen atoms), DPCA-30 (a compound in which m in Formulae (Z-1) to (Z-3) is 1, the number of groups represented by Formula (Z-2) is 3, and all of R^{1′}s represent hydrogen atoms), DPCA-60 (a compound in which m in Formulae (Z-1) to (Z-3) is 1, the number of groups represented by Formula (Z-2) is 6, and all of R^{1′}s represent hydrogen atoms), and DPCA-120 (a compound in which m in Formulae (Z-1) to (Z-3) is 2, the number of groups represented by Formula (Z-2) is 6, and all of R^{1′}s represent hydrogen atoms).

Examples of a suitable aspect of the second polymerizable compound also include a compound represented by Formula (Z-4) or Formula (Z-5).

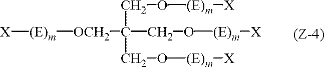

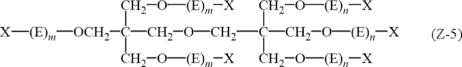

In Formulae (Z-4) and (Z-5), E’s each independently represent —((CH₂)_{y}CH2O)— or ((CH₂)_{y}CH(CH₃)O)—, y’s each independently represent an integer of 0 to 10, and X’s each independently represent a (meth)acryloyl group, a hydrogen atom, or a carboxylic acid group.

In Formula (Z-4), the total number of (meth)acryloyl groups is 3 or 4, m’s each independently represent an integer of 0 to 10, and the total number of m’s is an integer of 0 to 40.

In Formula (Z-5), the total number of (meth)acryloyl groups is 5 or 6, n’s each independently represent an integer of 0 to 10, and the total number of n’s is an integer of 0 to 60.

In Formula (Z-4), m is preferably an integer of 0 to 6 and more preferably an integer of 0 to 4.

In addition, the total number of m’s is preferably an integer of 2 to 40, more preferably an integer of 2 to 16, and still more preferably an integer of 4 to 8.

In Formula (Z-5), n is preferably an integer of 0 to 6 and more preferably an integer of 0 to 4.

In addition, the total number of n’s is preferably an integer of 3 to 60, more preferably an integer of 3 to 24, and still more preferably an integer of 6 to 12.

Furthermore, a form in which a terminal on the oxygen atom side of —((CH₂)_{y}CH2O)—or ((CH₂)_{yC}H(CH₃)O)— in Formula (Z-4) or Formula (Z-5) is bonded to X is preferable.

The compound represented by Formula (Z-4) or Formula (Z-5) may be used alone or in combination of two or more thereof. In particular, an aspect in which a mixture of a compound in which all of six X’s in Formula (Z-5) are acryloyl groups and a compound in which at least one among the six X’s is a hydrogen atom is preferable. With such a configuration, the developability can be further improved.

Among the compounds represented by Formula (Z-4) or Formula (Z-5), a pentaerythritol derivative and/or a dipentaerythritol derivative is more preferable.

Examples of the second polymerizable compound include dipentaerythritol triacrylate (as a commercially available product, KAYARAD D-330; manufactured by Nippon Kayaku Co., Ltd.), dipentaerythritol tetraacrylate (as a commercially available product, KAYARAD D-320; manufactured by Nippon Kayaku Co., Ltd.), dipentaerythritol penta(meth)acrylate (as a commercially available product, KAYARAD D-310; manufactured by Nippon Kayaku Co., Ltd.), dipentaerythritol hexa(meth)acrylate (as a commercially available product, KAYARAD DPHA; manufactured by Nippon Kayaku Co., Ltd., and A-DPH-12E; manufactured by Shin-Nakamura Chemical Co., Ltd.), and a structure (for example, SR454 and SR499 commercially available from Sartomer) in which an ethylene glycol residue or a propylene glycol residue is between these (meth)acryloyl groups. Oligomer types thereof can also be used.

In addition, examples thereof also include NK ESTER A-TMMT (pentaerythritol tetraacrylate, manufactured by Shin-Nakamura Chemical Co., Ltd.), KAYARAD RP-1040, KAYARAD DPEA-12LT, KAYARAD DPHA LT, KAYARAD RP-3060, and KAYARAD DPEA-12 (manufactured by Nippon Kayaku Co., Ltd.).

A content of the polymerizable compound in the composition according to the embodiment of the present invention is not particularly limited, but from the viewpoint that the effect of the present invention is more excellent, the content is preferably 5% to 35% by mass, more preferably 10% to 30% by mass, and still more preferably 15% to 25% by mass with respect to the total solid content of the composition.

The polymerizable compound may be used alone or in combination of two or more thereof. In a case where two or more polymerizable compounds are used in combination, the total content thereof is preferably within the above-described range.

In a case where the composition according to the embodiment of the present invention includes the first polymerizable compound and the second polymerizable compound, from the viewpoint that the effect of the present invention is more excellent, a mass ratio (second polymerizable compound/first polymerizable compound) of the content of the second polymerizable compound to the content of the first polymerizable compound in the composition is preferably 1/99 to 99/1, more preferably 30/70 to 95/5, and still more preferably 30/70 to 90/10.

### Polymerization Initiator

The composition according to the embodiment of the present invention includes a polymerization initiator.

The polymerization initiator is not particularly limited, and known polymerization initiators can be used. Examples of the polymerization initiator include a photopolymerization initiator and a thermal polymerization initiator, and a photopolymerization initiator is preferable. In addition, as the polymerization initiator, a so-called radical polymerization initiator is preferable.

Examples of the thermal polymerization initiator include an azo compound such as 2,2′-azobisisobutyronitrile (AIBN), 3-carboxypropionitrile, azobismalononitrile, and dimethyl-(2,2′)-azobis(2-methylpropionate) [V-601] and an organic peroxide such as benzoyl peroxide, lauroyl peroxide, and potassium persulfate.

Specific examples of the polymerization initiator include the thermal polymerization initiator described in pp. 65 to 148 of “Ultraviolet Curing System” (published by Sogo Gijutsu Center, 1989) written by Kiyomi KATO.

The photopolymerization initiator is not particularly limited as long as the photopolymerization initiator can initiate the polymerization of the polymerizable compound, and known photopolymerization initiators can be used. As the photopolymerization initiator, for example, a photopolymerization initiator exhibiting photosensitivity from an ultraviolet range to a visible light range is preferable. In addition, the photopolymerization initiator may be an activator which generates active radicals by causing a certain action with a photoexcited sensitizer, or an initiator which initiates cationic polymerization according to the type of the polymerizable compound.

Examples of the photopolymerization initiator include a halogenated hydrocarbon derivative (for example, a compound including a triazine skeleton, a compound including an oxadiazole skeleton, or the like), an acyl phosphine compound such as acyl phosphine oxide, hexaaryl biimidazole, an oxime compound such as an oxime derivative, an organic peroxide, a thio compound, a ketone compound, an aromatic onium salt, an aminoacetophenone compound, and hydroxyacetophenone.

Regarding specific examples of the photopolymerization initiator, reference can be made to, for example, paragraphs 0265 to 0268 of JP2013-029760A, the contents of which are incorporated into the present specification.

Examples of the photopolymerization initiator include the aminoacetophenone-based initiator described in JP1998-291969A (JP-H10-291969A) and the acyl phosphine-based initiator described in JP4225898B.

Examples of the hydroxyacetophenone compound include Omnirad-184, Omnirad-1173, Omnirad-500, Omnirad-2959, and Omnirad-127 (trade names, all manufactured by IGM RESINS B.V.).

Examples of the aminoacetophenone compound include Omnirad-907, Omnirad-369, and Omnirad-379EG (trade names, all manufactured by IGM RESINS B.V.), which are commercially available products. Examples of the aminoacetophenone compound also include the compound which is described in JP2009-191179A and whose absorption wavelength is matched to a light source having a long wavelength such as a wavelength of 365 nm or a wavelength of 405 nm.

Examples of the acyl phosphine compound include Omnirad-819 and Omnirad-TPO (trade names, both manufactured by IGM RESINS B.V.), which are commercially available products.

### Oxime Compound

As the photopolymerization initiator, an oxime ester-based polymerization initiator (oxime compound) is preferable.

In particular, an oxime compound has high sensitivity and high polymerization efficiency, easily designs the content of the light shielding pigment in the composition to be high, and thus is preferable.

Examples of the oxime compound include the compound described in JP2001-233842A, the compound described in JP2000-080068A, and the compound described in JP2006-342166A.

Examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Furthermore, the compounds described in J. C. S. Perkin II (1979) pp. 1653 to 1660, J. C. S. Perkin II (1979) pp. 156 to 162, Journal of Photopolymer Science and Technology (1995) pp. 202 to 232, JP2000-066385A, JP2000-080068A, JP2004-534797A, and JP2006-342166A can also be mentioned.

Examples of a commercially available product thereof also include IRGACURE-OXE01 (manufactured by BASF SE), IRGACURE-OXE02 (manufactured by BASF SE), IRGACURE-OXE03 (manufactured by BASF SE), and IRGACURE-OXE04 (manufactured by BASF SE). In addition, examples thereof also include TR-PBG-304 (manufactured by TRONLY), ADEKA ARKLS NCI-730, ADEKA ARKLS NCI-831, and ADEKA ARKLS NCI-930 (manufactured by ADEKA CORPORATION), and N-1919 (carbazole and oxime ester skeleton-containing photoinitiator (manufactured by ADEKA CORPORATION)). In addition, examples thereof also include Omnirad 1316 (IGM Resins B.V.).

In addition, examples of oxime compounds other than the above-described oxime compounds include the compound which is described in JP2009-519904A and in which oxime is linked to a N-position of carbazole; the compound which is described in US7626957B and in which a hetero substituent is introduced into a benzophenone moiety; the compounds which are described in JP2010-015025A and US2009/292039A and in which a nitro group is introduced into the moiety of a coloring agent; the ketoxime compound described in WO2009/131189A; the compound which is described in US7556910B and includes a triazine skeleton and an oxime skeleton in the same molecule; and the compound which is described in JP2009-221114A, has an absorption maximum at 405 nm, and exhibits favorable sensitivity with respect to a light source of a g-line.

Reference can be made to, for example, paragraphs 0274 and 0275 of JP2013-029760A, the contents of which are incorporated into the present specification.

Specifically, as the oxime compound, a compound represented by Formula (OX-1) is preferable. In addition, a N—O bond in the oxime compound may be an (E) isomer, a (Z) isomer, or a mixture of an (E) isomer and a (Z) isomer.

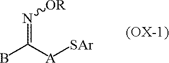

In Formula (OX-1), R and B each independently represent a monovalent substituent, A represents a divalent organic group, and Ar represents an aryl group.

In Formula (OX-1), the monovalent substituent represented by R is preferably a group of monovalent non-metal atom.

Examples of the group of monovalent non-metal atom include an alkyl group, an aryl group, an acyl group, an alkoxycarbonyl group, an aryloxycarbonyl group, a heterocyclic group, an alkylthiocarbonyl group, and an arylthiocarbonyl group. In addition, these groups may have one or more substituents. Furthermore, each of the substituents may be further substituted with another substituent.

Examples of the substituent include a halogen atom, an aryloxy group, an alkoxycarbonyl group or an aryloxycarbonyl group, an acyloxy group, an acyl group, an alkyl group, and an aryl group.

As the monovalent substituent represented by B in Formula (OX-1), an aryl group, a heterocyclic group, an arylcarbonyl group, or a heterocyclic carbonyl group is preferable, and an aryl group or a heterocyclic group is more preferable. These groups may have one or more substituents. Examples of the substituents include the above-described substituents.

As the divalent organic group represented by A in Formula (OX-1), an alkylene group having 1 to 12 carbon atoms, a cycloalkylene group, or an alkynylene group is preferable. These groups may have one or more substituents. Examples of the substituents include the above-described substituents.

Examples of the photopolymerization initiator also include a fluorine atom-containing oxime compound. Examples of the fluorine atom-containing oxime compound include the compound described in JP2010-262028A; the compounds 24 and 36 to 40 described in JP2014-500852A; and the compound (C-3) described in JP2013-164471A. The contents thereof are incorporated into the present specification.

Examples of the polymerization initiator also include compounds represented by Formulae (1) to (4).

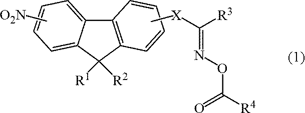

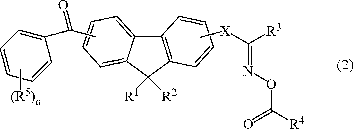

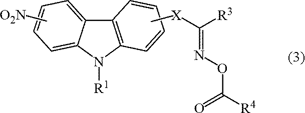

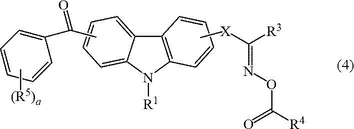

In Formula (1), R¹ and R² each independently represent an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms, in a case where R¹ and R² each represent a phenyl group, the phenyl groups may be bonded to each other to form a fluorene group, R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a direct bond or a carbonyl group.

In Formula (2), R¹, R², R³, and R⁴ have the same definitions as R¹, R², R³, and R⁴ in Formula (1), R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a direct bond or a carbonyl group, and a represents an integer of 0 to 4.

In Formula (3), R¹ represents an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms, R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a direct bond or a carbonyl group.

In Formula (4), R¹, R³, and R⁴ have the same definitions as R¹, R³, and R⁴ in Formula (3), R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a direct bond or a carbonyl group, and a represents an integer of 0 to 4.

Examples of the compounds represented by Formula (1) and Formula (2) include the compound described in paragraphs 0076 to 0079 of JP2014-137466A. The contents thereof are incorporated into the present specification.

In addition, as the polymerization initiator, a compound represented by Formula (1) is also preferable.

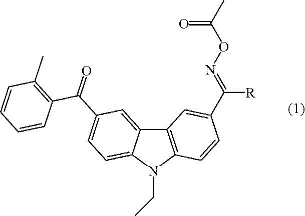

In Formula (1), R represents a group represented by Formula (1a).

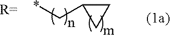

In Formula (1a), n represents an integer of 1 to 5. m represents an integer of 1 to 6. * represents a bonding position.

m is preferably 3 or 4.

For example, the compound represented by Formula (1) can be synthesized according to the synthesis method described in JP2012-519191A.

Specific examples of an oxime compound preferably used in the composition are shown below.

Furthermore, as the oxime compound, the compounds described in Table 1 of WO2015/036910A can also be mentioned, the contents of which are incorporated into the present specification.

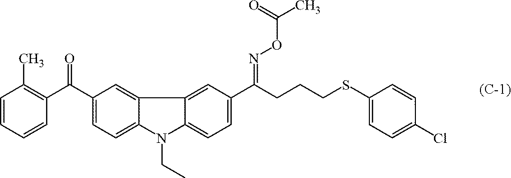 [SMILES: CCn1c2ccc(C(=O)c3ccccc3C)cc2c2cc(/C(CCCSc3ccc(Cl)cc3)=N/OC(C)=O)ccc21]

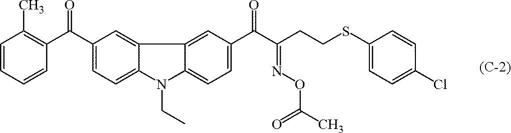 [SMILES: CCn1c2ccc(C(=O)/C(CCSc3ccc(Cl)cc3)=N/OC(C)=O)cc2c2cc(C(=O)c3ccccc3C)ccc21]

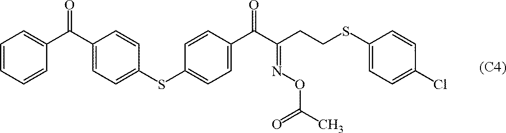 [SMILES: CC(=O)O/N=C(\CCSc1ccc(Cl)cc1)C(=O)c1ccc(Sc2ccc(C(=O)c3ccccc3)cc2)cc1]

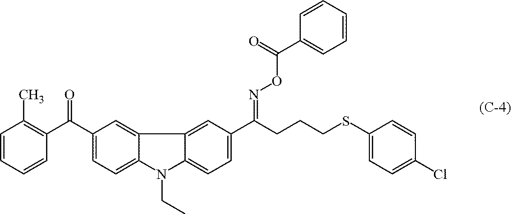 [SMILES: CCn1c2ccc(C(=O)c3ccccc3C)cc2c2cc(/C(CCCSc3ccc(Cl)cc3)=N/OC(=O)c3ccccc3)ccc21]

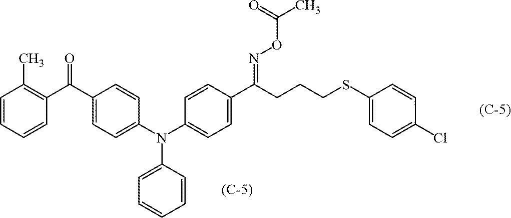 [SMILES: CC(=O)O/N=C(\CCCSc1ccc(Cl)cc1)c1ccc(N(c2ccccc2)c2ccc(C(=O)c3ccccc3C)cc2)cc1 ; "(C-5)"]

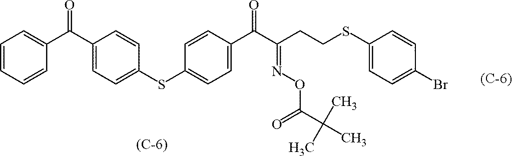 [SMILES: CC(C)(C)C(=O)O/N=C(\CCSc1ccc(Br)cc1)C(=O)c1ccc(Sc2ccc(C(=O)c3ccccc3)cc2)cc1 ; "(C-6)"]

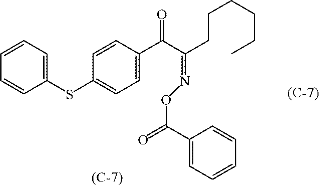 [SMILES: CCCCCC/C(=N/OC(=O)c1ccccc1)C(=O)c1ccc(Sc2ccccc2)cc1 ; "(C-7)"]

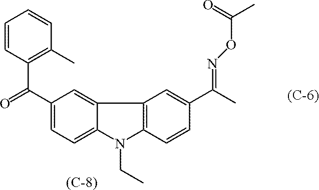 [SMILES: CCn1c2ccc(C(=O)c3ccccc3C)cc2c2cc(/C(C)=N/OC(C)=O)ccc21 ; "(C-8)"]

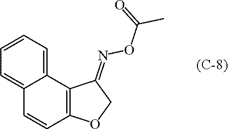 [SMILES: CC(=O)O/N=C1\COc2ccc3ccccc3c21]

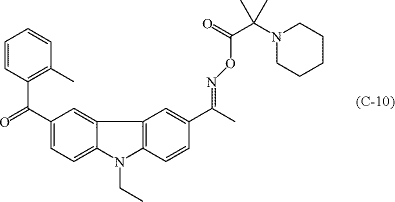 [SMILES: CCn1c2ccc(C(=O)c3ccccc3C)cc2c2cc(/C(C)=N/OC(=O)C(C)(C)N3CCCCC3)ccc21]

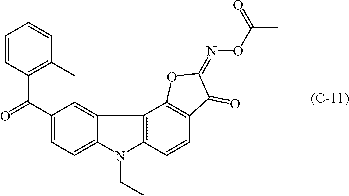 [SMILES: CCn1c2ccc(C(=O)c3ccccc3C)cc2c2c3c(ccc21)C(=O)/C(=N\OC(C)=O)O3]

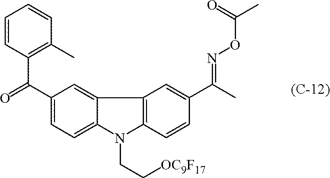

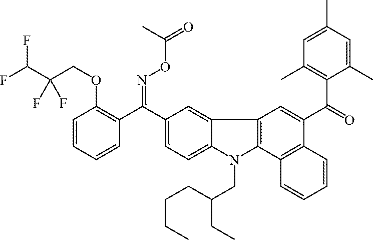 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

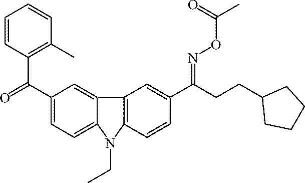 [SMILES: CCn1c2ccc(C(=O)c3ccccc3C)cc2c2cc(/C(CCC3CCCC3)=N/OC(C)=O)ccc21]

The oxime compound preferably has a maximal absorption wavelength in a wavelength range of 350 to 500 nm, more preferably has a maximal absorption wavelength in a wavelength range of 360 to 480 nm, and still more preferably has a high absorbance at wavelengths of 365 nm and 405 nm.

From the viewpoint of sensitivity, a molar absorption coefficient of the oxime compound at 365 nm or 405 nm is preferably 1,000 to 300,000, more preferably 2,000 to 300,000, and still more preferably 5,000 to 200,000.

The molar absorption coefficient of the compound can be measured by known methods, but for example, it is preferable that the measurement is carried out with an ultraviolet and visible spectrophotometer (Cary-5 spectrophotometer manufactured by Varian, Inc.) at a concentration of 0.01 g/L using ethyl acetate.

Two or more photopolymerization initiators may be used in combination, as needed.

In addition, as the photopolymerization initiator, the compounds described in paragraph 0052 of JP2008-260927A, paragraphs 0033 to 0037 of JP2010-097210A, and paragraph 0044 of JP2015-068893A can also be used, the contents of which are incorporated into the present specification.

As the polymerization initiator, from the viewpoint that the effect of the present invention is more excellent, an oxime ester-based polymerization initiator is preferable, and the above-described compound represented by Formula (1) is more preferable.

A content of the polymerization initiator in the composition according to the embodiment of the present invention is not particularly limited, but from the viewpoint that the effect of the present invention is more excellent, the content is preferably 0.5% to 20% by mass, more preferably 1.0% to 10% by mass, and still more preferably 1.5% to 8% by mass with respect to the total solid content of the composition.

The polymerization initiators may be used alone or in combination of two or more thereof. In a case where two or more polymerization initiators are used in combination, the total content thereof is preferably within the above-described range.

The composition according to the embodiment of the present invention may include a component other than the above-described components (carbon black, silica, barium sulfate, polymerizable compound, and polymerization initiator).

Hereinafter, other components will be described in detail.

One or more kinds of metal-containing particles selected from group consisting of metal nitride and metal oxynitride

The composition according to the embodiment of the present invention may include one or more kinds of metal-containing particles selected from the group consisting of a metal nitride and a metal oxynitride.

Examples of a metal element included in the metal nitride and the metal oxynitride include a metal element of Group 4; such as titanium (Ti) and zirconium (Zr), a metal element of Group 5, such as vanadium (V) and niobium (Nb); cobalt (Co), chromium (Cr), copper (Cu), manganese (Mn), ruthenium (Ru), iron (Fe), nickel (Ni), tin (Sn), and silver (Ag).

The above-described metal-containing particles are preferably a nitride or oxynitride of a metal element of Group 4, or a nitride or oxynitride of a metal element of Group 5. Furthermore, the above-described metal-containing particles are more preferably a nitride or oxynitride of titanium, a nitride or oxynitride of zirconium, a nitride or oxynitride of vanadium, or a nitride or oxynitride of niobium.

Furthermore, the nitride of titanium is titanium nitride, the nitride of zirconium is zirconium nitride, the nitride of vanadium is vanadium nitride, and the nitride of niobium is niobium nitride. In addition, the oxynitride of titanium is titanium oxynitride, the oxynitride of zirconium is zirconium oxynitride, the oxynitride of vanadium is vanadium oxynitride, and the oxynitride of niobium is niobium oxynitride.

An average primary particle diameter of the metal-containing particles is preferably 0.01 to 0.1 µm and more preferably 0.01 to 0.05 µm.

Examples of a commercially available product of the metal-containing particles include 13M, 13M-C, 13M-T, 12S, and UF-8 (manufactured by Mitsubishi Materials Corporation), titanium nitride particles (manufactured by Hefei Kai’er Nanometer Technology and Development Co., Ltd.), titanium nitride particles (manufactured by Nisshin Engineering Inc.), zirconium oxynitride particles (manufactured by Mitsubishi Materials Corporation), and NITRBLACK UB-1 and UB-2 (manufactured by Mitsubishi Materials Corporation).

### Copper Phthalocyanine and Copper Phthalocyanine Derivative (Copper Phthalocyanines)

The composition according to the embodiment of the present invention preferably includes copper phthalocyanines.

The copper phthalocyanine is intended to be a copper complex of phthalocyanine. The copper phthalocyanine derivative is intended to be a copper complex of phthalocyanine having a substituent (in a case where the substituent includes a polar group such as an acid group and a basic group, the copper complex may have a salt structure), and examples thereof include a copper complex of phthalocyanine having a substituent including a polar group such as an acid group and a basic group, and a salt thereof.

Examples of the acid group include a sulfonic acid group, a carboxylic acid group, and a phosphoric acid group, and from the viewpoint that the effect of the present invention is more excellent, a sulfonic acid group is preferable.

Examples of the basic group include a primary amino group, a secondary amino group, a tertiary amino group, a hetero ring including an N atom, and an amide group.

The salt is not particularly limited, and examples thereof include a halide salt, an alkali metal salt, and a quaternary ammonium salt.

Examples of a halide ion constituting the halide salt include a fluoride ion, a chloride ion, a bromide ion, and an iodide ion.

Examples of an alkali metal ion constituting the alkali metal salt include a lithium ion, a sodium ion, and a potassium ion.

Examples of a quaternary ammonium ion constituting the quaternary ammonium salt include a quaternary ammonium ion represented by Formula (NA).

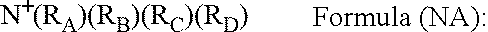

R_{A} to R_{D} each independently represent a hydrogen atom, an alkyl group, an alkenyl group, or an alkynyl group, which may have a substituent. Among them, R_{A} to R_{D} are preferably an alkyl group which may have a substituent. The substituent is not particularly limited, and examples thereof include a hydroxyl group.

The alkyl group, alkenyl group, and alkynyl group are preferably linear or branched.

The number of carbon atoms in the alkyl group is preferably 1 to 30 and more preferably 1 to 25.

The number of carbon atoms in the alkenyl group and the alkynyl group is preferably 2 to 30 and more preferably 2 to 25.

Examples of a suitable aspect of the quaternary ammonium ion represented by Formula (NA) include an aspect in which R_{A} and R_{B} are long chains (for example, the numbers of carbon atoms in R_{A} and R_{B} are each independently preferably 12 to 30 and more preferably 12 to 25), and Rc and R_{D} are short chains (for example, the numbers of carbon atoms in Rc and R_{D} are each independently preferably 1 to 10, more preferably 1 to 6, and it is still more preferable to be a methyl group).

From the viewpoint that the effect of the present invention is more excellent, the quaternary ammonium ion represented by Formula (NA) is preferable dimethyldioctadecylammonium.

As the copper phthalocyanines, from the viewpoint that the effect of the present invention is more excellent, a copper complex of phthalocyanine having a substituent including a sulfonic acid group or a salt thereof is preferable, a quaternary ammonium salt of a copper complex of phthalocyanine having a substituent including a sulfonic acid group is more preferable, and a salt composed of a copper complex of phthalocyanine having a substituent including a sulfonic acid group and dimethyldioctadecylammonium is still more preferable.

The substituent including a sulfonic acid group may be a sulfonic acid group or a group represented by *-L^{B}-sulfonic acid group (L^{B} represents a divalent linking group and * represents a bonding position). The divalent linking group represented by L^{B} is not particularly limited, and examples thereof include an alkylene group, an alkenylene group, an alkynylene group, —O—, —S—, —NR^{B}—, —CO—, and a group of a combination of these groups. R_{B} represents a hydrogen atom or an alkyl group having 1 to 6 carbon atoms. The above-described alkylene group, alkenylene group, and alkynylene group may further have a substituent.

Examples of the copper phthalocyanines include C. I. Pigment Blue 15:3.

In addition, examples of a commercially available product of the copper phthalocyanines include “5000” of “SOLSPERSE” series (manufactured by Lubrizol Japan Limited), and a copper phthalocyanine-3,4’,4”,4”’-tetrasulfonic acid tetrasodium salt available from Sigma-Aldrich Co., LLC.

In a case where the composition according to the embodiment of the present invention includes copper phthalocyanines, a content of the copper phthalocyanines in the composition according to the embodiment of the present invention is not particularly limited, but from the viewpoint that the effect of the present invention is more excellent, the content is preferably 0.5% by mass or more and more preferably 1.0% by mass or more with respect to the total solid content of the composition. Moreover, the upper limit value thereof is preferably 10.0% by mass or less, more preferably 8.0% by mass or less, and still more preferably 6.0% by mass or less.

The copper phthalocyanines may be used alone or in combination of two or more thereof. In a case where two or more copper phthalocyanines are used in combination, the total content thereof is preferably within the above-described range.

A mass ratio (carbon black/copper phthalocyanines) of the content of the carbon black to the content of the copper phthalocyanines is not particularly limited, but from the viewpoint that the effect of the present invention is more excellent, the mass ratio is preferably 4.0 to 99 and more preferably 10 to 40.

### Surfactant

The composition according to the embodiment of the present invention may include a surfactant. The surfactant contributes to improvement in coating properties of the composition.

Examples of the surfactant include a silicone-based surfactant, a fluorine-based surfactant, a nonionic surfactant, a cationic surfactant, and an anionic surfactant.

Among them, from the viewpoint that the effect of the present invention is more excellent, a silicone-based surfactant is preferable.

Examples of the silicone-based surfactant include a linear polymer consisting of a siloxane bond and a modified siloxane polymer with an organic group introduced in the side chain and/or the terminal.

Examples of the silicone-based surfactant include DOWSIL (registered trademark) series such as DC3PA, SH7PA, DC11PA, SH21PA, SH28PA, SH29PA, SH30PA, and SH8400 (all manufactured by Dow Corning Corporation); X-22-4952, X-22-4272, X-22-6266, KF-351A, K354L, KF-355A, KF-945, KF-640, KF-642, KF-643, X-22-6191, X-22-4515, KF-6000, KF-6004, KP-323, KP-341, KF-6001, and KF-6002 (all manufactured by Shin-Etsu Chemical Co., Ltd.); F-4440, TSF-4300, TSF-4445, TSF-4460, and TSF-4452 (all manufactured by Momentive Performance Materials Japan LLC); and BYK307, BYK323, and BYK330 (all manufactured by BYK-Chemie GmbH).

As a suitable aspect of the silicone-based surfactant, from the viewpoint that the effect of the present invention is more excellent, an aromatic group-modified silicone-based surfactant (silicone-based surfactant having an aromatic group) is preferable, and a phenyl-modified silicone-based surfactant (silicone-based surfactant having a phenyl group) is more preferable.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, and MEGAFACE F780 (all manufactured by DIC Corporation), FLUORAD FC430, FLUORAD FC431, and FLUORAD FC171 (all manufactured by Sumitomo 3M Limited), SURFLON S-382, SURFLON SC-101, SURFLON SC-103, SURFLON SC-104, SURFLON SC-105, SURFLON SC1068, SURFLON SC-381, SURFLON SC-383, SURFLON S393, and SURFLON KH-40 (all manufactured by ASAHI GLASS CO., LTD.), and PF636, PF656, PF6320, PF6520, and PF7002 (manufactured by OMNOVA Solutions Inc.).

As the fluorine-based surfactant, a block polymer can also be used, and examples thereof include the compound described in JP2011-089090A.

In a case where the composition according to the embodiment of the present invention includes a surfactant, a content of the surfactant in the composition according to the embodiment of the present invention is not particularly limited, but from the viewpoint that the effect of the present invention is more excellent, the content is preferably 0.001% to 2.0% by mass, more preferably 0.005% to 0.5% by mass, and still more preferably 0.01% to 0.1% by mass with respect to the total solid content of the composition.

The surfactant may be used alone or in combination of two or more thereof. In a case where two or more surfactants are used in combination, the total amount thereof is preferably within the above-described range.

### Resin

The composition according to the embodiment of the present invention may include a resin.

Examples of the resin include a dispersant and an alkali-soluble resin.

A molecular weight of the resin is more than 2000. In a case where the molecular weight of the resin is polydisperse, a weight-average molecular weight thereof is more than 2000.

### Dispersant

The composition preferably includes a dispersant. In the present specification, a dispersant means a compound different from the alkali-soluble resin which will be described later.

A content of the dispersant in the composition is not particularly limited, but is preferably 2% to 40% by mass, more preferably 5% to 30% by mass, and still more preferably 10% to 25% by mass with respect to the total solid content of the composition.

The dispersant may be used alone or in combination of two or more thereof. In a case where two or more dispersants are used in combination, the total content thereof is preferably within the above-described range.

As the dispersant, for example, known dispersants can be appropriately selected and used. Among them, a polymer compound is preferable.

Examples of the dispersant include a polymer dispersant [for example, polyamidoamine and a salt thereof, polycarboxylic acid and a salt thereof, high-molecular-weight unsaturated acid ester, modified polyurethane, modified polyester, modified poly(meth)acrylate, a (meth)acrylic copolymer, and a naphthalenesulfonic acid-formalin condensate], polyoxyethylene alkyl phosphoric acid ester, polyoxyethylene alkylamine, and a pigment derivative.

The polymer compound can be further classified into a linear polymer, a terminal-modified polymer, a graft polymer, and a block polymer based on the structure.

### Polymer Compound

The polymer compound acts to prevent the reaggregation of a substance to be dispersed by being adsorbed onto a surface of the substance to be dispersed, such as the carbon black and another pigment (hereinafter, the carbon black and the other pigment are collectively and simply referred to as a “pigment” as well) used in combination as desired. Therefore, a terminal-modified polymer, a graft (including a polymer chain) polymer, or a block polymer is preferable which includes a moiety anchored to the pigment surface.

The above-described polymer compound may include a curable group.

Examples of the curable group include an ethylenically unsaturated group (for example, a (meth)acryloyl group, a vinyl group, a styryl group, and the like), and a cyclic ether group (for example, an epoxy group, an oxetanyl group, and the like).

Among them, from the viewpoint that polymerization can be controlled by a radical reaction, as the curable group, an ethylenically unsaturated group is preferable. As the ethylenically unsaturated group, a (meth)acryloyl group is preferable.

The polymer compound including a curable group preferably includes one or more kinds selected from the group consisting of a polyester structure and a polyether structure. In this case, the polyester structure and/or the polyether structure may be included in a main chain, and as will be described later, in a case where the above-described polymer compound has a structural unit including a graft chain, the above-described graft chain may have a polyester structure and/or a polyether structure.

As the above-described polymer compound, a polymer compound in which the above-described graft chain has a polyester structure is more preferable.

The polymer compound preferably has a structural unit including a graft chain. In the present specification, the “structural unit” has the same definition as a “repeating unit”.

Such a polymer compound having the structural unit including a graft chain has an affinity with a solvent due to the graft chain, and thus is excellent in dispersibility of a pigment or the like and dispersion stability after the lapse of time. Moreover, due to the presence of the graft chain, the polymer compound having the structural unit including a graft chain has an affinity with a polymerizable compound or other resins which can be used in combination. As a result, residues are less likely to be generated in alkali development.

In a case where the graft chain is prolonged, a steric repulsion effect is enhanced, and thus the dispersibility of the pigment or the like is improved. Meanwhile, in a case where the graft chain is too long, adsorptive power to the pigment or the like is reduced, and thus the dispersibility of the pigment or the like tends to be reduced. Therefore, the number of atoms in the graft chain excluding hydrogen atoms is preferably 40 to 10000, more preferably 50 to 2000, and still more preferably 60 to 500.

Herein, the graft chain refers to a portion from the base (in a group which is branched off from the main chain, an atom bonded to the main chain) of a main chain of the copolymer to the terminal of a group branched off from the main chain.

The graft chain preferably includes a polymer structure, and examples of such a polymer structure include a poly(meth)acrylate structure (for example, a poly(meth)acrylic structure), a polyester structure, a polyurethane structure, a polyurea structure, a polyamide structure, and a polyether structure.

In order to improve interactive properties between the graft chain and the solvent, and thus enhance the dispersibility of the pigment or the like, the graft chain is preferably a graft chain having one or more kinds selected from the group consisting of a polyester structure, a polyether structure, and a poly(meth)acrylate structure, and more preferably a graft chain having at least one of a polyester structure or a polyether structure.

A macromonomer (a monomer which has a polymer structure and constitutes a graft chain by being bonded to the main chain of a copolymer) including such a graft chain is not particularly limited, but a macromonomer including a reactive double bond group can be suitably used.

As a commercial macromonomer, which corresponds to the structural unit including a graft chain included in the polymer compound and is suitably used for synthesizing the polymer compound, AA-6 (trade name, manufactured by TOAGOSEI CO., LTD.), AA-10 (trade name, manufactured by TOAGOSEI CO., LTD.), AB-6 (trade name, manufactured by TOAGOSEI CO., LTD.), AS-6 (trade name, manufactured by TOAGOSEI CO., LTD.), AN-6 (trade name, manufactured by TOAGOSEI CO., LTD.), AW-6 (trade name, manufactured by TOAGOSEI CO., LTD.), AA-714 (trade name, manufactured by TOAGOSEI CO., LTD.), AY-707 (trade name, manufactured by TOAGOSEI CO., LTD.), AY-714 (trade name, manufactured by TOAGOSEI CO., LTD.), AK-5 (trade name, manufactured by TOAGOSEI CO., LTD.), AK-30 (trade name, manufactured by TOAGOSEI CO., LTD.), AK-32 (trade name, manufactured by TOAGOSEI CO., LTD.), BLEMMER PP-100 (trade name, manufactured by NOF CORPORATION), BLEMMER PP-500 (trade name, manufactured by NOF CORPORATION), BLEMMER PP-800 (trade name, manufactured by NOF CORPORATION), BLEMMER PP-1000 (trade name, manufactured by NOF CORPORATION), BLEMMER 55-PET-800 (trade name, manufactured by NOF CORPORATION), BLEMMER PME-4000 (trade name, manufactured by NOF CORPORATION), BLEMMER PSE-400 (trade name, manufactured by NOF CORPORATION), BLEMMER PSE-1300 (trade name, manufactured by NOF CORPORATION), BLEMMER 43PAPE-600B (trade name, manufactured by NOF CORPORATION), or the like is used. Among them, AA-6 (trade name, manufactured by TOAGOSEI CO., LTD.), AA-10 (trade name, manufactured by TOAGOSEI CO., LTD.), AB-6 (trade name, manufactured by TOAGOSEI CO., LTD.), AS-6 (trade name, manufactured by TOAGOSEI CO., LTD.), AN-6 (trade name, manufactured by TOAGOSEI CO., LTD.), or BLEMMER PME-4000 (trade name, manufactured by NOF CORPORATION) is preferable.

The dispersant preferably has one or more structures selected from the group consisting of polymethyl acrylate, polymethyl methacrylate, and cyclic or chain-like polyester, more preferably has one or more structures selected from the group consisting of polymethyl acrylate, polymethyl methacrylate, and chain-like polyester, and still more preferably has one or more structures selected from the group consisting of a polymethyl acrylate structure, a polymethyl methacrylate structure, a polycaprolactone structure, and a polyvalerolactone structure. The dispersant may be a dispersant having the above-described structure alone in one dispersant, or may be a dispersant having a plurality of these structures in one dispersant.

Herein, the polycaprolactone structure refers to a structure including a structure, which is obtained by ring opening of ε-caprolactone, as a repeating unit. The polyvalerolactone structure refers to a structure including a structure, which is obtained by ring opening of δ-valerolactone, as a repeating unit.

Specific examples of the dispersant having a polycaprolactone structure include dispersants in which j and k in Formula (1) and Formula (2) are each 5. Moreover, specific examples of the dispersant having a polyvalerolactone structure include dispersants in which j and k in Formula (1) and Formula (2) are each 4.

Specific examples of the dispersant having a polymethyl acrylate structure include dispersants in which in Formula (4), X⁵ is a hydrogen atom and R⁴ is a methyl group. Moreover, specific examples of the dispersant having a polymethyl methacrylate structure include dispersants in which in Formula (4), X⁵ is a methyl group and R⁴ is a methyl group.

### Structural Unit Including Graft Chain

As the structural unit including a graft chain, a structural unit represented by any of Formulae (1) to (4) is preferable.

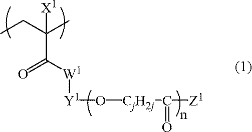

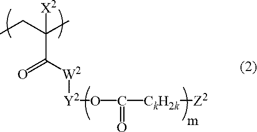

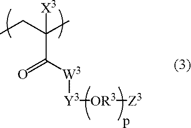

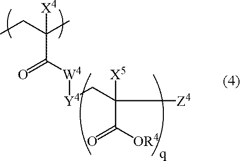

In Formulae (1) to (4), W¹, W², W³, and W⁴ each independently represent an oxygen atom or NH. As W¹, W², W³, and W⁴, an oxygen atom is preferable.

In Formulae (1) to (4), X¹, X², X³, X⁴, and X⁵ each independently represent a hydrogen atom or a monovalent organic group. From the viewpoint of the restriction on synthesis, X¹, X², X³, X⁴, and X⁵ are preferably each independently a hydrogen atom or an alkyl group having 1 to 12 carbon atoms (the number of carbon atoms), more preferably each independently a hydrogen atom or a methyl group, and still more preferably each independently a methyl group.

In Formulae (1) to (4), Y¹, Y², Y³, and Y⁴ each independently represent a divalent linking group, and the linking group has no particular restriction on a structure. Specific examples of the divalent linking groups represented by Y¹, Y², Y³, and Y⁴ include linking groups represented by the following (Y-1) to (Y-21). In the following structures, A and B mean moieties bonded to the left terminal group and the right terminal group in Formulae (1) to (4), respectively. Among the following structures, from the viewpoint of simplicity of synthesis, (Y-2) or (Y-13) is more preferable.

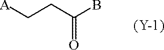

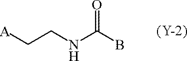

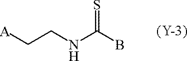

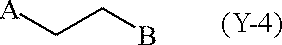

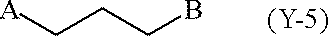

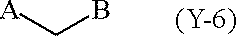

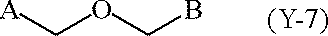

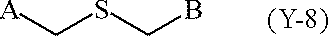

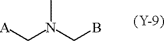

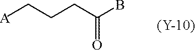

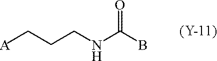

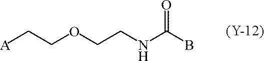

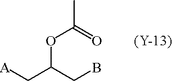

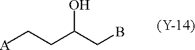

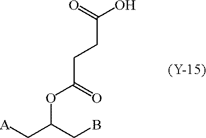

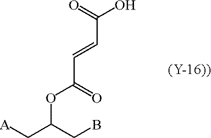

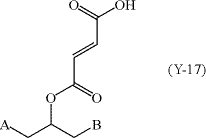

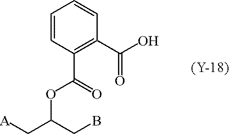

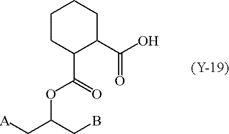

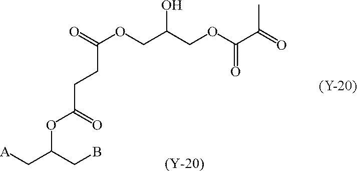

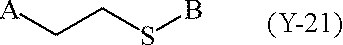

In Formulae (1) to (4), Z¹, Z², Z³, and Z⁴ each independently represent a monovalent organic group. The structure of the organic group is not particularly limited, but specific examples thereof include an alkyl group, a hydroxyl group, an alkoxy group, an aryloxy group, a heteroaryloxy group, an alkylthioether group, an arylthioether group, a heteroarylthioether group, and an amino group. Among them, particularly from the viewpoint of improvement in the dispersibility, the organic groups represented by Z¹, Z², Z³, and Z⁴ are each preferably a group exhibiting a steric repulsion effect, and more preferably each independently an alkyl group or alkoxy group having 5 to 24 carbon atoms, and still more preferably each independently a branched alkyl group having 5 to 24 carbon atoms, a cyclic alkyl group having 5 to 24 carbon atoms, or an alkoxy group having 5 to 24 carbon atoms. Furthermore, the alkyl group included in the alkoxy group may be any of linear, branched, or cyclic.

In Formulae (1) to (4), n, m, p, and q each independently represent an integer of 1 to 500.

In addition, in Formulae (1) and (2), j and k each independently represent an integer of 2 to 8. From the viewpoints of the viscosity stability over time and developability of the composition, j and k in Formulae (1) and (2) are each preferably an integer of 4 to 6 and more preferably 5.

In Formulae (1) and (2), n and m are each preferably an integer of 10 or more and more preferably an integer of 20 or more. Moreover, in a case where the dispersant has a polycaprolactone structure and a polyvalerolactone structure, the sum of the repetition number of the polycaprolactone structure and the repetition number of the polyvalerolactone structure is preferably an integer of 10 or more and more preferably an integer of 20 or more.

In Formula (3), R³ represents a branched or linear alkylene group, and is preferably an alkylene group having 1 to 10 carbon atoms and more preferably an alkylene group having 2 or 3 carbon atoms. In a case where p is 2 to 500, a plurality of R³′s may be the same as or different from each other.

In Formula (4), R⁴ represents a hydrogen atom or a monovalent organic group, and the monovalent organic group has no particular limitation on a structure. As R⁴, a hydrogen atom, an alkyl group, an aryl group, or a heteroaryl group is preferable, and a hydrogen atom or an alkyl group is more preferable. In a case where R⁴ is an alkyl group, as the alkyl group, a linear alkyl group having 1 to 20 carbon atoms, a branched alkyl group having 3 to 20 carbon atoms, or a cyclic alkyl group having 5 to 20 carbon atoms is preferable, a linear alkyl group having 1 to 20 carbon atoms is more preferable, and a linear alkyl group having 1 to 6 carbon atoms is still more preferable. In a case where q in Formula (4) is 2 to 500, a plurality of X⁵′s and a plurality of R⁴′s in the graft copolymer may be respectively the same as or different from each other.

In addition, the polymer compound can include a structural unit which includes two or more different structures and includes a graft chain. That is, the structural units which are represented by Formulae (1) to (4) and have structures different from one another may be included in a molecule of the polymer compound, and in a case where n, m, p, and q in Formulae (1) to (4) each represent an integer equal to or greater than 2, in Formulae (1) and (2), structures in which j and k are different from each other may be included in the side chain, and in Formulae (3) and (4), a plurality of R³′s, a plurality of R⁴′s, and a plurality of X⁵′s in the molecule may be respectively the same as or different from each other.

The structural unit (for example, the structural units represented by Formulae (1) to (4)) including a graft chain in the polymer compound is preferably within a range of 2% to 90% by mass and more preferably within a range of 5% to 30% by mass, in terms of mass with respect to the total mass of the polymer compound. In a case where the structural unit including a graft chain is within the above-described range, the dispersibility of the pigment is high and the developability of the cured film after exposure is good.

### Hydrophobic Structural Unit

The polymer compound preferably includes a hydrophobic structural unit which is different from the structural unit including a graft chain (that is, the structural unit does not correspond to the structural unit including a graft chain). Here, in the present specification, the hydrophobic structural unit is a structural unit which does not have an acid group (for example, a carboxylic acid group, a sulfonic acid group, a phosphoric acid group, a phenolic hydroxyl group, or the like).

As the hydrophobic structural unit, a structural unit derived from (corresponding to) a compound (monomer) having a ClogP value of 1.2 or more is preferable, and a structural unit derived from a compound having a ClogP value of 1.2 to 8 is more preferable. By doing so, the effects of the present invention can be more reliably exhibited.

The ClogP value is a value calculated by a program “CLOGP” available from Daylight Chemical Information System, Inc. This program provides a value of “calculated logP” calculated by the fragment approach (see the following documents) of Hansch and Leo. The fragment approach is based on a chemical structure of a compound, and the logP value of the compound is estimated by dividing the chemical structure into partial structures (fragments) and summing up degrees of contribution to logP which are assigned to the fragments. Details thereof are described in the following documents. In the present specification, a ClogP value calculated by a program CLOGP v4.82 is used.

A. J. Leo, Comprehensive Medicinal Chemistry, Vol. 4, C. Hansch, P. G. Sammnens, J. B. Taylor and C. A. Ramsden, Eds., p. 295, Pergamon Press, 1990, C. Hansch & A. J. Leo. Substituent Constants For Correlation Analysis in Chemistry and Biology. John Wiley & Sons. A. J. Leo. Calculating logPoct from structure. Chem. Rev., 93, 1281 to 1306, 1993.

The logP refers to a common logarithm of a partition coefficient P, is a physical property value that shows how a certain organic compound is partitioned in an equilibrium of a two-phase system consisting of oil (generally, 1-octanol) and water by using a quantitative numerical value, and is expressed by the following expression.

logP = log(Coil/Cwater)In the expression, Coil represents a molar concentration of a compound in an oil phase, and Cwater represents a molar concentration of the compound in a water phase.

The greater the positive logP value based on 0, the higher the oil solubility, and the greater the absolute value of negative logP, the higher the water solubility. Accordingly, the value of logP has a negative correlation with the water solubility of an organic compound and is widely used as a parameter for estimating the hydrophilicity and hydrophobicity of an organic compound.

The content of the hydrophobic structural unit in the polymer compound is preferably within a range of 10% to 90% and more preferably within a range of 20% to 80%, in terms of mass with respect to the total mass of the polymer compound. In a case where the content is within the above-described range, sufficient pattern formation can be obtained.

### Functional Group Capable of Forming Interaction With Pigment or the Like

A functional group capable of forming interaction with the pigment or the like (for example, a light shielding pigment) can be introduced into the polymer compound. Herein, it is preferable that the polymer compound further has a structural unit including a functional group capable of forming interaction with the pigment or the like.

Examples of the functional group capable of forming interaction with the pigment or the like include an acid group, a basic group, a coordinating group, and a reactive functional group.

In a case where the polymer compound includes an acid group, a basic group, a coordinating group, or a reactive functional group, it is preferable that the polymer compound has a structural unit including an acid group, a structural unit including a basic group, a structural unit including a coordinating group, or a structural unit including a reactive functional group.

In particular, in a case where the polymer compound further contains, as an acid group, an alkali-soluble group such as a carboxylic acid group, developability for pattern formation by alkali development can be imparted to the polymer compound.

That is, in a case where an alkali-soluble group is introduced into the polymer compound, in the composition, the polymer compound as a dispersant making a contribution to the dispersion of the pigment or the like has alkali solubility. The composition including such a polymer compound is excellent in light shielding properties of a cured film formed by exposure, and improves alkali developability of a non-exposed portion.

Furthermore, in a case where the polymer compound includes a structural unit including an acid group, the polymer compound is easily compatible with the solvent, and coating properties also tend to be improved.

It is presumed that this is because the acid group in the structural unit including an acid group easily interacts with the pigment or the like, the polymer compound stably disperses the pigment or the like, the viscosity of the polymer compound dispersing the pigment or the like is reduced, and thus the polymer compound is also easily dispersed in a stable manner.

Here, the structural unit including an alkali-soluble group as an acid group may be the same as or different from the structural unit including a graft chain, but the structural unit including an alkali-soluble group as an acid group is a structural unit different from the hydrophobic structural unit (that is, the structural unit does not correspond to the hydrophobic structural unit).

Examples of the acid group, which is the functional group capable of forming interaction with the pigment or the like, include a carboxylic acid group, a sulfonic acid group, a phosphoric acid group, and a phenolic hydroxyl group, and one or more kinds selected from the group consisting of a carboxylic acid group, a sulfonic acid group, and a phosphoric acid group is preferable, and a carboxylic acid group is more preferable. The carboxylic acid group has favorable adsorptive power to the pigment or the like and high dispersibility.

That is, it is preferable that the polymer compound includes a structural unit including one or more kinds selected from the group consisting of a carboxylic acid group, a sulfonic acid group, and a phosphoric acid group.

The polymer compound may have one or more of the structural units including an acid group.

The polymer compound may or may not include the structural unit including an acid group, but in a case where the polymer compound includes the structural unit including an acid group, the content thereof, in terms of mass with respect to the total mass of the polymer compound is preferably 5% to 80% by mass, and more preferably 10% to 60% by mass from the viewpoint of suppressing damage of the image intensity by alkali development.

Examples of the basic group, which is the functional group capable of forming interaction with the pigment or the like, include a primary amino group, a secondary amino group, a tertiary amino group, a hetero ring including a N atom, and an amide group, and a preferred basic group is a tertiary amino group from the viewpoints of favorable adsorptive power to the pigment or the like and high dispersibility. The polymer compound may include one or more of these basic groups.

The polymer compound may or may not include the structural unit including a basic group, but in a case where the polymer compound includes the structural unit including a basic group, the content thereof, in terms of mass with respect to the total mass of the polymer compound is preferably 0.01% to 50% by mass, and more preferably 0.01% to 30% by mass from the viewpoint of suppressing developability inhibition.

Examples of the coordinating group and the reactive functional group which are the functional groups capable of forming interaction with the pigment or the like include an acetyl acetoxy group, a trialkoxysilyl group, an isocyanate group, an acid anhydride, and an acid chloride. A preferred functional group is an acetyl acetoxy group from the viewpoints of favorable adsorptive power to the pigment or the like and high dispersibility of the pigment or the like. The polymer compound may have one or more of these groups.

The polymer compound may or may not include the structural unit including a coordinating group or the structural unit including a reactive functional group, but in a case where the polymer compound includes the structural unit including a coordinating group or the structural unit including a reactive functional group, the content thereof, in terms of mass with respect to the total mass of the polymer compound is preferably 10% to 80% by mass, and more preferably 20% to 60% by mass from the viewpoint of suppressing developability inhibition.

From the viewpoint of the interaction with the pigment or the like, the viscosity stability over time, and the permeability into a developer, the content of the structural unit including a functional group capable of forming interaction with the pigment or the like is preferably 0.05% to 90% by mass, more preferably 1.0% to 80% by mass, and still more preferably 10% to 70% by mass with respect to the total mass of the polymer compound.

### Other Structural Units

In addition, for the purpose of improving various performances such as image intensity, as long as the effects of the present invention are not impaired, the polymer compound may further have other structural units (for example, a structural unit including a functional group or the like having an affinity with the solvent which will be described later) which have various functions and are different from the structural unit including a graft chain, the hydrophobic structural unit, and the structural unit including a functional group capable of forming interaction with the pigment or the like.

Examples of such other structural units include structural units derived from radically polymerizable compounds selected from acrylonitriles or methacrylonitriles.

The polymer compound may use one or more of these other structural units, and the content thereof is preferably 0% to 80% by mass and more preferably 10% to 60% by mass, in terms of mass with respect to the total mass of the polymer compound. In a case where the content is within the above-described range, sufficient pattern formability is maintained.

### Physical Properties of Polymer Compound

An acid value of the polymer compound is preferably 0 to 250 mgKOH/g, more preferably 10 to 200 mgKOH/g, and still more preferably 30 to 180 mgKOH/g.

In a case where the acid value of the polymer compound is 160 mgKOH/g or less, pattern peeling during development of the cured film after exposure is more effectively suppressed. In addition, in a case where the acid value of the polymer compound is 10 mgKOH/g or more, the alkali developability is improved. Furthermore, in a case where the acid value of the polymer compound is 20 mgKOH/g or more, the precipitation of the pigment or the like can be further suppressed, the number of coarse particles can be further reduced, and the viscosity stability over time of the composition can be further improved.

In the present specification, the acid value can be calculated, for example, from the average content of acid groups in the compound. Moreover, a resin having a desired acid value can be obtained by changing the content of the structural unit including an acid group, which is a constituent component of the resin.

A weight-average molecular weight of the polymer compound is preferably 4,000 to 300,000, more preferably 5,000 to 200,000, still more preferably 6,000 to 100,000, and particularly preferably 10,000 to 50,000.

The polymer compound can be synthesized based on known methods.

Examples of the polymer compound include “DA-7301” manufactured by Kusumoto Chemicals, Ltd., “Disperbyk-101 (polyamidoamine phosphate), 107 (carboxylic acid ester), 110 (copolymer including an acid group), 111 (phosphoric acid-based dispersant), 130 (polyamide), 161, 162, 163, 164, 165, 166, 167, 170, and 190 (polymeric copolymer)” and “BYK-P104 and P105 (high-molecular-weight unsaturated polycarboxylic acid)” manufactured by BYK-Chemie GmbH, “EFKA 4047, 4050 to 4010 to 4165 (based on polyurethane), EFKA 4330 to 4340 (block copolymer), 4400 to 4402 (modified polyacrylate), 5010 (polyester amide), 5765 (high-molecular-weight polycarboxylate), 6220 (fatty acid polyester), and 6750 (azo pigment derivative)” manufactured by EFKA, “AJISPER PB821, PB822, PB880, and PB881” manufactured by Ajinomoto Fine-Techno Co., Inc., “FLOWLEN TG-710 (urethane oligomer)” and “POLYFLOW No. 50E and No. 300 (acrylic copolymer)” manufactured by KYOEISHA CHEMICAL Co., LTD., “DISPARLON KS-860, 873SN, 874, #2150 (aliphatic polyvalent carboxylic acid), #7004 (polyether ester), DA-703-50, DA-705, and DA-725” manufactured by Kusumoto Chemicals, Ltd., “DEMOL RN, N (naphthalenesulfonic acid-formalin polycondensate), MS, C, and SN-B (aromatic sulfonic acid-formalin polycondensate)”, “HOMOGENOL L-18 (polymeric polycarboxylic acid)”, “EMULGEN 920, 930, 935, and 985 (polyoxyethylene nonylphenyl ether)”, and “ACETAMIN 86 (stearylamine acetate)” manufactured by Kao Corporation, “22000 (azo pigment derivative), 13240 (polyester amine), 3000, 12000, 17000, 20000, 27000 (polymer including a functional portion on a terminal portion), 24000, 28000, 32000, and 38500 (graft copolymer)” manufactured by Lubrizol Japan Limited, “NIKKOL T106 (polyoxyethylene sorbitan monooleate), and MYS-IEX (polyoxyethylene monostearate)” manufactured by Nikko Chemicals Co., Ltd., HINOACT T-8000E and the like manufactured by Kawaken Fine Chemicals Co., Ltd., an organosiloxane polymer KP341 manufactured by Shin-Etsu Chemical Co., Ltd., “W001: cationic surfactant”, nonionic surfactants such as polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and a sorbitan fatty acid ester, and anionic surfactants such as “W004, W005, and W017” manufactured by Yusho Co., Ltd., “EFKA-46, EFKA-47, EFKA-47EA, EFKA POLYMER 100, EFKA POLYMER 400, EFKA POLYMER 401, and EFKA POLYMER 450” manufactured by MORISHITA & CO., LTD., polymer dispersants such as “DISPERSE AID 6, DISPERSE AID 8, DISPERSE AID 15, and DISPERSE AID 9100” manufactured by SAN NOPCO LIMITED, “ADEKA PLURONIC (registered trademark) L31, F38, L42, L44, L61, L64, F68, L72, P95, F77, P84, F87, P94, L101, P103, F108, L121, and P-123” manufactured by ADEKA CORPORATION, and “IONET (trade name) S-20” manufactured by Sanyo Chemical Industries, Ltd. In addition, ACRYBASE FFS-6752 and ACRYBASE FFS-187 can also be used.

In addition, an amphoteric resin including an acid group and a basic group is also preferable. The amphoteric resin is preferably a resin having an acid value of 5 mgKOH/g or more and an amine value of 5 mgKOH/g or more.

Examples of a commercially available product of the amphoteric resin include DISPERBYK-130, DISPERBYK-140, DISPERBYK-142, DISPERBYK-145, DISPERBYK-180, DISPERBYK-187, DISPERBYK-191, DISPERBYK-2001, DISPERBYK-2010, DISPERBYK-2012, DISPERBYK-2025, and BYK-9076 manufactured by BYK-Chemie GmbH, and AJISPER PB821, AJISPER PB822, and AJISPER PB881 manufactured by Ajinomoto Fine-Techno Co., Inc.

These polymer compounds may be used alone or in combination of two or more thereof.

Furthermore, regarding the polymer compound, reference can be made to the polymer compound described in paragraphs 0127 to 0129 of JP2013-249417A, the contents of which are incorporated into the present specification.

In addition, in addition to the above-described polymer compounds, examples of the dispersant include the graft copolymer described in paragraphs 0037 to 0115 of JP2010-106268A (corresponding to paragraphs 0075 to 0133 of US2011/0124824A), the contents of which can be incorporated by reference into the present specification.

Moreover, in addition to the above-described dispersant, examples thereof include the polymer compound described in paragraphs 0028 to 0084 of JP2011-153283A (corresponding to paragraphs 0075 to 0133 of US2011/0279759A) which includes a constituent component having a side chain structure formed by bonding of acid groups through a linking group, the contents of which can be incorporated by reference into the present specification.

Furthermore, examples of the dispersant include the resin described in paragraphs 0033 to 0049 of JP2016-109763A can also be used, the contents of which are incorporated into the present specification.

In addition, as the dispersant, a resin having a repeating unit including a polyalkyleneimine structure and a polyester structure (hereinafter, also referred to as a “resin X1”) can also be suitably used. It is preferable that the repeating unit including a polyalkyleneimine structure and a polyester structure includes the polyalkyleneimine structure in a main chain and includes the polyester structure as a graft chain.

An acid value of the resin X1 is preferably 10 to 100 mgKOH/g and more preferably 20 to 80 mgKOH/g. An amine value of the resin X1 is preferably 5 mgKOH/g or more, more preferably 20 mgKOH/g or more, and still more preferably 30 mgKOH/g or more. The upper limit value thereof is preferably, for example, 100 mgKOH/g or less.

A weight-average molecular weight of the resin X1 is not particularly limited, but for example, 3,000 or more is preferable, 4,000 or more is more preferable, 5,000 or more is still more preferable, and 6,000 or more is particularly preferable. Moreover, the upper limit value thereof is, for example, preferably 300,000 or less, more preferably 200,000 or less, still more preferably 100,000 or less, and particularly preferably 50,000 or less.

### Alkali-Soluble Resin

The composition preferably includes an alkali-soluble resin. In the present specification, the alkali-soluble resin means a resin including a group (hereinafter, also simply referred to as an “alkali-soluble group”; examples thereof include an acid group such as a carboxylic acid group) which promotes alkali solubility, and a resin different from the dispersant described above.

A content of the alkali-soluble resin in the composition is not particularly limited, but is preferably 1% to 30% by mass, more preferably 2% to 20% by mass, and still more preferably 5% to 15% by mass with respect to the total solid content of the composition.

The alkali-soluble resin may be used alone or in combination of two or more thereof. In a case where two or more alkali-soluble resins are used in combination, the total content thereof is preferably within the above-described range.

As the alkali-soluble resin, a resin including at least one alkali-soluble group in a molecule is mentioned, and examples thereof include a polyhydroxystyrene resin, a polysiloxane resin, a (meth)acrylic resin, a (meth)acrylamide resin, a (meth)acryl/(meth)acrylamide copolymer resin, an epoxy-based resin, and a polyimide resin.

Examples of the alkali-soluble resin include a copolymer of an unsaturated carboxylic acid and an ethylenically unsaturated compound.

The unsaturated carboxylic acid is not particularly limited, but examples thereof include monocarboxylic acids such as (meth)acrylic acid, crotonic acid, and vinyl acetate; dicarboxylic acid such as itaconic acid, maleic acid, and fumaric acid or an acid anhydride thereof; and polyvalent carboxylic acid monoesters such as mono(2-(meth)acryloyloxyethyl)phthalate.

Examples of a copolymerizable ethylenically unsaturated compound include methyl (meth)acrylate. Moreover, the compounds described in paragraph 0027 of JP2010-097210A and paragraphs 0036 and 0037 of JP2015-068893A can also be used, the contents of which are incorporated into the present specification.

As the alkali-soluble resin, from the viewpoint that the effect of the present invention is more excellent, an alkali-soluble resin including a curable group is also preferable.

Examples of the curable group also include the curable groups which may be included in the polymer compound described above, and preferred ranges thereof are also the same.

Examples of an aspect of the alkali-soluble resin including a curable group include an acrylic resin including an ethylenically unsaturated group in a side chain. An acrylic resin including an ethylenically unsaturated group in a side chain can be obtained, for example, by addition-reacting a carboxylic acid group of an acrylic resin including the carboxylic acid group with an ethylenically unsaturated compound including a glycidyl group or an alicyclic epoxy group.

The alkali-soluble resin including a curable group is preferably an alkali-soluble resin having a curable group in the side chain, or the like. Examples of the alkali-soluble resin including a curable group include DIANAL NR series (manufactured by Mitsubishi Rayon Co., Ltd.), Photomer 6173 (COOH-containing polyurethane acrylic oligomer, manufactured by Diamond Shamrock Co., Ltd.), VISCOAT R-264 and KS resist 106 (all manufactured by OSAKA ORGANIC CHEMICAL INDUSTRY LTD.), CYCLOMER P series (for example, ACA230AA) and PLACCEL CF200 series (all manufactured by DAICEL CORPORATION), Ebecryl 3800 (manufactured by DAICEL-ALLNEX LTD.), and ACRYCURE RD-F8 (manufactured by NIPPON SHOKUBAI CO., LTD.).

Examples of the alkali-soluble resin include the radical polymers which include a carboxylic acid group in a side chain and are described in JP1984-044615A (JP-S59-044615A), JP1979-34327B (JP-S54-34327B), JP1983-012577B (JP-S58-012577B), JP1979-025957B (JP-S54-025957B), JP1979-092723A (JP-S54-092723A), JP1984-053836A (JP-S59-053836A), and JP1984-071048A (JP-S59-071048A); the acetal-modified polyvinyl alcohol-based binder resins which include an alkali-soluble group and are described in EP993966B, EP1204000B, and JP2001-318463A; polyvinyl pyrrolidone; polyethylene oxide; polyether or the like which is a reaction product of alcohol-soluble nylon, 2,2-bis-(4-hydroxyphenyl)-propane, and epichlorohydrin; and the polyimide resin described in WO2008/123097A.

Examples of the alkali-soluble resin also include the compound described in paragraphs 0225 to 0245 of JP2016-075845A can also be used, the contents of which are incorporated into the present specification.

Examples of the alkali-soluble resin also include a polyimide precursor. The polyimide precursor means a resin obtained by causing an addition polymerization reaction between a compound including an acid anhydride group and a diamine compound at a temperature of 40° C. to 100° C.

The alkali-soluble resin includes a repeating unit represented by Formula (A) and a repeating unit represented by Formula (B), and it is preferable that a content of the repeating unit represented by Formula (A) is 30% by mass or more with repeating unit to all repeating units included in the alkali-soluble resin.

By using the above-described alkali-soluble resin, a phase separation structure between the alkali-soluble resin and other components (for example, the dispersant) is likely to occur in the cured film formed of the composition, and the reflectivity of the formed cured film is further reduced.

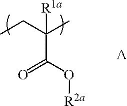

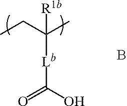

In Formula (A), R^{1a} represents a hydrogen atom or a methyl group.

R^{2a} represents a linear or branched alkyl group having 1 to 12 carbon atoms.

The number of carbon atoms in the alkyl group represented by R^{2a} is preferably 1 to 8, more preferably 2 to 6, and still more preferably 3 or 4. Moreover, a linear alkyl group is preferable.

In Formula (B), R^{1b} represents a hydrogen atom or a methyl group.

L^{b} represents a single bond or a divalent linking group.

The type of the divalent linking group is not particularly limited, and examples thereof include a divalent hydrocarbon group (which may be a divalent saturated hydrocarbon group or a divalent aromatic hydrocarbon group; the divalent saturated hydrocarbon group may be any of linear forms, branched forms, or cyclic forms, and preferably has 1 to 10 carbon atoms, and examples thereof include an alkylene group; the divalent aromatic hydrocarbon group preferably has 5 to 10 carbon atoms, and examples thereof include a phenylene group; other than these groups, the divalent hydrocarbon group may be an alkenylene group or an alkynylene group), a divalent heterocyclic group, —O—, —S—, —SO₂—, —NR^{A}—, —CO—(—C(═O)—), —COO—(—C(═O)O—), —NR^{A}—CO—, —SO₃—, —SO₂NR^{A}—, and a group of a combination of two or more kinds thereof. Here, R^{A} represents a hydrogen atom or an alkyl group (preferably having 1 to 10 carbon atoms).

A content of the repeating unit represented by Formula (A) is preferably 30% by mass or more, and more preferably 45% by mass or more with respect to all repeating units included in the alkali-soluble resin. The upper limit is not particularly limited, but is preferably 90% by mass or less and more preferably 60% by mass or less.

A content of the repeating unit represented by Formula (B) is preferably 3% to 60% by mass, and more preferably 5% to 30% by mass with respect to all repeating units included in the alkali-soluble resin.

The alkali-soluble resin including the repeating unit represented by Formula (A) and the repeating unit represented by Formula (B) may include a repeating unit other than the repeating units.

Examples of other repeating units include a repeating unit having a curable group.

Examples of the curable group also include the curable groups which may be included in the polymer compound described above, and preferred ranges thereof are also the same.

A content of the repeating unit having a curable group is preferably 3% to 40% by mass, and more preferably 5% to 30% by mass with respect to all repeating units included in the alkali-soluble resin.

In addition, an acid value of the alkali-soluble resin including the repeating unit represented by Formula (A) and the repeating unit represented by Formula (B) is preferably 10 to 200 mgKOH/g, more preferably 20 to 100 mgKOH/g, and still more preferably 30 to 80 mgKOH/g.

In a case where the composition according to the embodiment of the present invention includes a resin, a content of the resin in the composition according to the embodiment of the present invention is not particularly limited, but from the viewpoint that the effect of the present invention is more excellent, the content is preferably 3% to 70% by mass, more preferably 9% to 40% by mass, and still more preferably 9% to 35% by mass.

The resin may be used alone or in combination of two or more thereof. In a case where two or more resins are used in combination, the total content thereof is preferably within the above-described range.

### Solvent

The composition according to the embodiment of the present invention may include a solvent.

The solvent is not particularly limited and a known solvent can be used, and examples thereof include an organic solvent and water.

A solid content of the composition is preferably 10% to 90% by mass, more preferably 10% to 45% by mass, and still more preferably 15% to 35% by mass with respect to the total mass of the composition. That is, the content of the solvent in the composition is not particularly limited, but it is preferable that the solid content of the composition is adjusted to the above-described content.

The solvent may be used alone or in combination of two or more thereof. In a case where two or more kinds of solvents are used in combination, the content thereof is preferably adjusted so that the total solid content of the composition is within the above-described range.

Specific examples of the organic solvent include acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetylacetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, γ-butyrolactone, butyl acetate, methyl lactate, N-methyl-2-pyrrolidone, and ethyl lactate, but the organic solvent is not limited thereto.

### Epoxy Group-Containing Compound (Adhesive)

The composition according to the embodiment of the present invention may include an epoxy group-containing compound.

Examples of the epoxy group-containing compound include a compound having one or more epoxy groups, and a compound having two or more epoxy group is preferable. It is preferable that 1 to 100 epoxy groups are included.

The upper limit thereof may be 10 or less or 5 or less, for example. The lower limit thereof is preferably 2 or more.

In addition, the epoxy group-containing compound means a component different from the above-described dispersant, alkali-soluble resin, and polymerizable compound.

An epoxy equivalent (= molecular weight of epoxy group-containing compound/number of epoxy groups) of the epoxy group-containing compound is preferably equal to or less than 500 g/equivalent, more preferably 100 to 400 g/equivalent, and still more preferably 100 to 300 g/equivalent.

The epoxy group-containing compound may be a low-molecular-weight compound (for example, the molecular weight is less than 2,000) or a high-molecular-weight compound (macromolecule) (for example, the molecular weight is 2,000 or more, and in a case of a polymer, the weight-average molecular weight is 2,000 or more).

A weight-average molecular weight of the epoxy group-containing compound is preferably 200 to 100,000 and more preferably 500 to 50,000.

The upper limit of the weight-average molecular weight is more preferably 10,000 or less, still more preferably 5,000 or less, and particularly preferably 3,000 or less.

A commercially available product may be used for the epoxy group-containing compound. Examples thereof include EHPE3150 (manufactured by DAICEL CORPORATION) and EPICLON N-695 (manufactured by DIC CORPORATION). Moreover, examples of the epoxy group-containing compound also include the compounds described in paragraphs 0034 to 0036 of JP2013-011869A, paragraphs 0147 to 0156 of JP2014-043556A, and paragraphs 0085 to 0092 of JP2014-089408A. The contents of the above-described documents are incorporated into the present specification.

In a case where the composition according to the embodiment of the present invention includes an epoxy group-containing compound, a content of the epoxy group-containing compound in the composition is preferably 0.1% to 10% by mass, more preferably 0.5% to 8% by mass, and still more preferably 1.0% to 6% by mass with respect to the total solid content in the composition.

The epoxy group-containing compound may be used alone or in combination of two or more thereof. In a case where the above-described composition includes two or more epoxy group-containing compounds, the total content thereof is preferably within the above-described range.

### Silane Coupling Agent (Adhesive)

The composition according to the embodiment of the present invention may include a silane coupling agent.

The silane coupling agent functions as an adhesive which improves adhesiveness between a substrate and a cured film in a case where the cured film is formed on the substrate.

The silane coupling agent is a compound including a hydrolyzable group and other functional groups in a molecule. In addition, the hydrolyzable group such as an alkoxy group is bonded to the silicon atom.

The hydrolyzable group refers to a substituent which is directly bonded to a silicon atom and can form a siloxane bond by a hydrolysis reaction and/or a condensation reaction. Examples of the hydrolyzable group include a halogen atom, an alkoxy group, an acyloxy group, and an alkenyloxy group. In a case where the hydrolyzable group includes a carbon atom, the number of carbon atoms is preferably 6 or less and more preferably 4 or less. In particular, an alkoxy group having 4 or less carbon atoms or an alkenyloxy group having 4 or less carbon atoms is preferable.

Furthermore, in a case where a cured film is formed on a substrate, in order to improve adhesiveness between the substrate and the cured film, the silane coupling agent preferably does not include a fluorine atom and a silicon atom (here, a silicon atom to which a hydrolyzable group is bonded is excluded), and desirably does not include a fluorine atom, a silicon atom (here, a silicon atom to which a hydrolyzable group is bonded is excluded), an alkylene group substituted with a silicon atom, a linear alkyl group having 8 or more carbon atoms, and a branched alkyl group having 3 or more carbon atoms.

The silane coupling agent may include an ethylenically unsaturated group such as a (meth)acryloyl group. In a case where the silane coupling agent includes an ethylenically unsaturated group, the number thereof is preferably 1 to 10 and more preferably 4 to 8. Moreover, the silane coupling agent (for example, a compound which includes a hydrolyzable group and an ethylenically unsaturated group and has a molecular weight of 2000 or less) including an ethylenically unsaturated group does not correspond to the above-described polymerizable compound.

Examples of the silane coupling agent include 3-glycidoxypropyl trimethoxysilane, 3-glycidoxypropyl triethoxysilane, 3-glycidoxypropyl methyldimethoxysilane, 3-glycidoxypropyl methyldiethoxysilane, vinyltrimethoxysilane, and vinyltriethoxysilane.

In a case where the composition according to the embodiment of the present invention includes a silane coupling agent, a content of the silane coupling agent in the composition is preferably 0.1% to 10% by mass, more preferably 0.5% to 8% by mass, and still more preferably 1.0% to 6% by mass with respect to the total solid content of the composition.

The above-described composition may include one silane coupling agent alone or two or more silane coupling agents. In a case where the composition includes two or more silane coupling agents, the total amount thereof may be within the above-described range.

### Ultraviolet Absorber

The composition according to the embodiment of the present invention may include an ultraviolet absorber. As a result, the pattern shape of the cured film formed by exposure can be made into a more excellent (fine) shape.

Examples of the ultraviolet absorber include a salicylate-based ultraviolet absorber, a benzophenone-based ultraviolet absorber, a benzotriazole-based ultraviolet absorber, a substituted acrylonitrile-based ultraviolet absorber, and a triazine-based ultraviolet absorber. In addition, examples thereof also include the compound described in paragraphs 0137 to 0142 of JP2012-068418A (corresponding to paragraphs 0251 to 0254 of US2012/0068292A) can be used, the contents of which can be incorporated by reference into the present specification.

In addition to the above-described compounds, examples thereof also include a diethylamino-phenylsulfonyl-based ultraviolet absorber (manufactured by DAITO CHEMICAL CO., LTD., trade name: UV-503).

Examples of the ultraviolet absorber also include the compounds exemplified in paragraphs 0134 to 0148 of JP2012-032556A.

In a case where the composition according to the embodiment of the present invention includes the ultraviolet absorber, a content of the ultraviolet absorber is preferably 0.001% to 15% by mass, more preferably 0.01% to 10% by mass, and still more preferably 0.1% to 5% by mass with respect to the total solid content of the composition.

### Other Colorants

The composition may include any colorant, and the colorant can be selected from a pigment, a dye, an infrared absorber, or the like. However, the colorant is a colorant other than the above-described carbon black, barium sulfate, and metal-containing particles.

### Other Optional Components

The composition may further include optional components other than the above-described components. Examples thereof include a polymerization inhibitor, a sensitizer, a co-sensitizer, a crosslinking agent, a curing accelerator, a filler, a heat curing accelerator, a plasticizer, a diluent, and an oil sensitizing agent, and known additives such as an adhesion promoter to the surface of the substrate and other auxiliaries (for example, conductive particles, a filling agent, an anti-foaming agent, a flame retardant, a leveling agent, a peeling accelerator, an antioxidant, a fragrance, a surface tension adjuster, a chain transfer agent, and the like) may be added as necessary.

Regarding these components, reference can be made to, for example, the descriptions in paragraphs 0183 to 0228 of JP2012-003225A (corresponding to paragraphs 0237 to 0309 of US2013/0034812A), paragraphs 0101, 0102, 0103, 0104, and 0107 to 0109 of JP2008-250074A, and paragraphs 0159 to 0184 of JP2013-195480A, the contents of which are incorporated into the present specification.

### Method for Producing Composition

A method for producing the composition according to the embodiment of the present invention is not particularly limited, and a known method can be adopted.

Among them, as the method for producing the composition according to the embodiment of the present invention, a method of, first, producing a dispersion composition in which the carbon black is dispersed, and further mixing the obtained dispersion composition with other components is preferable.

The dispersion composition is preferably prepared by mixing carbon black, barium sulfate, copper phthalocyanines, a resin (preferably, a dispersant), and a solvent.

The dispersion composition can be prepared by mixing the respective components described above by known mixing methods (for example, mixing methods using a stirrer, a homogenizer, a high-pressure emulsification device, a wet-type pulverizer, or a wet-type disperser).

After preparing the dispersion composition, the composition according to the embodiment of the present invention can be prepared by mixing the above-described dispersion composition, the silica, the resin (alkali-soluble resin), the polymerizable compound, the polymerization initiator, and the solvent. In addition, components such as an adhesive and a surfactant can also be formulated.

In a case of preparing the composition, the respective components may be formulated at once, or each of the components may be dissolved or dispersed in a solvent and then sequentially formulated. In addition, the input order and the operation conditions during the formulation are not particularly limited.

For the purpose of removing foreign substances, reducing defects, and the like, the composition is preferably filtered with a filter.

The filter can be used without particular limitation as long as the filter has been used in the related art in a filtration application or the like. Examples of the filter include filters made of a fluororesin such as polytetrafluoroethylene (PTFE), a polyamide-based resin such as nylon, a polyolefin-based resin (having a high density and an ultrahigh molecular weight) such as polyethylene and polypropylene (PP), or the like. Among these materials, polypropylene (including high-density polypropylene) and nylon are preferable.

The composition preferably does not include impurities such as a metal, a halogen-containing metal salt, an acid, and an alkali. A content of impurities included in these materials is preferably 1 ppm or less, more preferably 1 ppb or less, still more preferably 100 ppt or less, and particularly preferably 10 ppt or less, and it is most preferable that the impurities are substantially not included (the content is equal to or less than the detection limit of the measuring device).

Furthermore, the impurities can be measured using an inductively coupled plasma mass spectrometer (manufactured by Agilent Technologies, Inc., Agilent 7500 cs model).

### Cured Film

In the present specification, the “cured film” is a film formed by subjecting a composition layer formed of the composition according to the embodiment of the present invention to a curing treatment such as an exposure treatment.

### Method for Manufacturing Cured Film

A method for manufacturing a cured film preferably includes a composition layer forming step, an exposure step, and a development step.

By going through the above-described steps, for example, a patterned cured film can be formed.

Hereinafter, each of the steps will be described.

### Composition Layer Forming Step

In the composition layer forming step, prior to exposure, the composition is applied onto a support or the like to a composition layer. As the support, for example, a substrate for a solid-state imaging element, in which an imaging element (light-receiving element) such as a charge coupled device (CCD) or a complementary metal-oxide semiconductor (CMOS) is provided on a substrate (for example, a silicon substrate), can be used. In addition, in order to improve adhesion with the upper layer, prevent the diffusion of substances, and planarize the surface of the substrate, an undercoat layer may be provided on the support, as needed.

Examples of a method for applying the composition onto the support include various coating methods such as a slit coating method, an ink jet method, a spin coating method, a cast coating method, a roll coating method, and a screen printing method. A film thickness of the composition layer is preferably 0.1 to 10 µm, more preferably 0.2 to 5 µm, and still more preferably 0.2 to 3 µm. The composition layer applied on the support can be dried (pre-baked) at a temperature of 50° C. to 140° C. for 10 to 300 seconds using a hot plate, an oven, or the like.

### Exposure Step

The exposure step is a step of exposing the composition layer formed in the composition layer forming step by irradiating the composition layer with actinic rays or radiations. Specifically, the exposure step is a step of exposing the composition layer formed in the composition layer forming step by irradiating the composition layer with actinic rays or radiations to cure a light irradiation region of the composition layer.

The method of light irradiation is not particularly limited, but light irradiation is preferably performed through a photo mask having a patterned opening portion.

The exposure is preferably performed by irradiation with radiation, ultraviolet rays such as a g-line, an h-line, and an i-line are particularly preferable as the radiations which can be used during the exposure, and a high-pressure mercury lamp is preferable as a light source. The irradiation intensity is preferably 5 to 1,500 mJ/cm² and more preferably 10 to 1000 mJ/cm².

In a case where the composition includes a thermal polymerization initiator, it is also preferable to heat the composition layer in the above-described exposure step. A heating temperature is not particularly limited, but is preferably 80° C. to 250° C. A heating time is not particularly limited, but is preferably 30 to 300 seconds.

Furthermore, in a case where the composition layer is heated in the exposure step, the exposure step may serve as a post-heating step which will be described later. In other words, in a case where the composition layer is heated in the exposure step, the method for manufacturing a cured film may not include the post-heating step.

### Development Step

The development step is a step of performing a development treatment on the composition layer after the exposure. By this step, the composition layer in the light exposed region in the exposure step is eluted, and only the photocured portion remains. For example, in a case where the light irradiation is performed through a photo mask having a pattern-like opening portion in the exposure step, a patterned cured film is obtained.

A type of a developer used in the development step is not particularly limited, but an alkali developer which does not damage the underlying imaging element and circuit or the like is desirable.

The development temperature is 20° C. to 30° C., for example.

The development time is 20 to 90 seconds, for example. In order to further remove the residues, in recent years, the development may be performed for 120 to 180 seconds. Furthermore, in order to improve residue removability, a step of shaking off the developer every 60 seconds and further supplying a fresh developer may be repeated several times.

The alkali developer is preferably an alkaline aqueous solution which is prepared by dissolving an alkaline compound in water so that the concentration thereof is 0.001% to 10% by mass (preferably 0.01% to 5% by mass).

Examples of the alkaline compound include sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo[5.4.0]-7-undecene (among them, organic alkalis are preferable.).

Furthermore, in a case where the alkaline compound is used as an alkali developer, the alkaline compound is generally subjected to a washing treatment with water after development.

### Post-Baking

A heating treatment (post-baking) is preferably performed after the exposure step. The post-baking is a heating treatment after development to complete the curing. The heating temperature is preferably 240° C. or lower and more preferably 220° C. or lower. The lower limit thereof is not particularly limited, but is preferably 50° C. or higher and more preferably 100° C. or higher, in consideration of an efficient and effective treatment.

The post-baking can be performed continuously or batchwise by using a heating unit such as a hot plate, a convection oven (hot-air circulating dryer), and a radio-frequency heater.

The post-baking is preferably performed in an atmosphere of a low oxygen concentration. The oxygen concentration is preferably 19% by volume or less, more preferably 15% by volume or less, still more preferably 10% by volume or less, particularly preferably 7% by volume or less, and most preferably 3% by volume or less. The lower limit thereof is not particularly limited, but is practically 10 ppm by volume or more.

In addition, the curing may be completed by irradiation with ultraviolet rays (UV) instead of the post-baking by heating.

In this case, it is preferable that the above-described composition further includes an UV curing agent. The UV curing agent is preferably an UV curing agent which can be cured at a wavelength shorter than 365 nm that is an exposure wavelength of a polymerization initiator added for a lithography step by ordinary i-line exposure. Examples of the UV curing agent include CIBA IRGACURE 2959 (trade name). In a case where UV irradiation is performed, the composition layer is preferably a material which is cured at a wavelength of 340 nm or less. The lower limit value of the wavelength is not particularly limited, but is generally 220 nm or more. In addition, an exposure amount of the UV irradiation is preferably 100 to 5000 mJ, more preferably 300 to 4000 mJ, and still more preferably 800 to 3500 mJ. The UV curing step is preferably performed after the lithography step because low-temperature curing is more effectively performed. As an exposure light source, an ozoneless mercury lamp is preferably used.

### Physical Properties of Cured Film and Application of Cured Film

### Physical Properties of Cured Film

From the viewpoint that excellent light shielding properties are exhibited, in a cured film obtained by using the composition according to the embodiment of the present invention, an optical density (OD) per film thickness of 2.0 µm in a wavelength range of 400 to 1000 nm is preferably 3.0 or more and more preferably 3.5 or more. In addition, the upper limit value thereof is not particularly limited, but is preferably 10 or less, in general. The cured film can be preferably used as a light shielding film.

In the present specification, the expression that the optical density per film thickness of 2.0 µm in a wavelength range of 400 to 1000 nm is 3.0 or more means that an optical density per film thickness of 2.0 µm in the entire wavelength range of 400 to 1000 nm is 3.0 or more.

In the present specification, as a method for measuring the optical density of the cured film, a cured film is first formed on a glass substrate, and the optical density is measured using a spectrophotometer (for example, U-4100 manufactured by Hitachi High-Technologies Corporation).

The film thickness of the cured film is, for example, preferably 0.1 to 4.0 µm and more preferably 1.0 to 2.5 µm. The cured film may be thinner or thicker than the above range depending on the application.

Moreover, from the viewpoint that excellent low reflection properties are exhibited, in the cured film obtained by using the composition according to the embodiment of the present invention, the maximum reflectivity (incidence angle: 5°) per film thickness of 2.0 µm in a wavelength range of 400 to 1100 nm is preferably less than 5% and more preferably less than 3%. The lower limit value thereof is not particularly limited, but is generally 0% or more.

In the present specification, as a method for measuring the maximum reflectivity of the cured film, a cured film is first formed on a glass substrate, and using a spectrometer (for example, VAR unit of a spectrometer V7200 manufactured by JASCO Corporation), a reflectivity spectrum with respect to the incidence angle of 5° is obtained, and a reflectivity of light having a wavelength showing the maximum reflectivity in the wavelength range of 400 to 1100 nm is obtained.

In addition, the cured film is suitable for a light shielding member, a light shielding film, an antireflection member, and an antireflection film of optical filters and modules used in portable instruments such as a personal computer, a tablet PC, a mobile phone, a smartphone, and a digital camera; office automation (OA) instruments such as a printer composite machine and a scanner; industrial instruments such as monitoring camera, a barcode reader, an automated teller machine (ATM), a high-speed camera, an instrument having a personal authentication function using face image authentication; in-vehicle camera instruments; medical camera instruments such as an endoscope, a capsule endoscope, and a catheter; a biological sensor, a biosensor, a military reconnaissance camera, a camera for a three-dimensional map, a camera for observing weather and sea, a camera for a land resource exploration, space instruments such as an exploration camera for the astronomy of the space and a deep space target; and the like.

The cured film can also be used in applications of a micro light emitting diode (LED), a micro organic light emitting diode (OLED), and the like. The cured film is suitable for an optical filter and an optical film used in the micro LED and the micro OLED and for a member which imparts a light shielding function or an antireflection function.

Examples of the micro LED and the micro OLED include the examples described in JP2015-500562A and JP2014-533890A.

The cured film is also suitable as an optical filter and an optical film used in a quantum dot sensor and a quantum dot solid-state imaging element. In addition, the cured film is suitable as a member which imparts a light shielding function or an antireflection function. Examples of the quantum dot sensor and the quantum dot solid-state imaging element include the examples described in US2012/37789A and WO2008/131313A.

Light shielding film, solid-state imaging element, and solid-state imaging device

It is also preferable that the cured film obtained by using the composition according to the embodiment of the present invention is used as a so-called light shielding film. It is also preferable that such a light shielding film is used in a solid-state imaging element.

Furthermore, the light shielding film is one of the preferable applications in the cured film obtained by using the composition according to the embodiment of the present invention, and the light shielding film can be manufactured in the same manner as the method for manufacturing a cured film described above. Specifically, a light shielding film can be manufactured by applying the composition to a substrate to form a composition layer, and performing exposure and development on the composition layer.

In addition, the solid-state imaging element according to the embodiment of the present invention is a solid-state imaging element including the cured film (light shielding film) obtained by using the composition according to the embodiment of the present invention.

As described above, the solid-state imaging element according to the embodiment of the present invention includes the above-described cured film (light shielding film). An aspect in which the solid-state imaging element includes the cured film (light shielding film) is not particularly limited, and examples thereof include an aspect in which a plurality of photodiodes and light-receiving elements consisting of polysilicon or the like constituting a light-receiving area of a solid-state imaging element (a CCD image sensor, a CMOS image sensor, or the like) are provided on a substrate, and the solid-state imaging element includes the cured film on a surface side (for example, a portion other than light receiving sections and/or pixels for adjusting color, and the like) of a support on which the light-receiving elements are formed or on a side opposite to the surface on which the light-receiving elements are formed.

In addition, in a case where the cured film (light shielding film) is used as a light attenuating film, for example, by disposing a light attenuating film so that a part of light passes through the light attenuating film and then is incident on a light-receiving element, the dynamic range of the solid-state imaging element can be improved.

The solid-state imaging device includes the above-described solid-state imaging element.

### Image Display Device

It is also preferable that the cured film obtained by using the composition according to the embodiment of the present invention is also preferably applied to an image display device.

An image display device according to the embodiment of the present invention includes the cured film obtained by using the composition according to the embodiment of the present invention.

Examples of the aspect in which the image display device has a cured film include an aspect in which a cured film is contained in a black matrix and a color filter including such a black matrix is used in an image display device.

Next, a black matrix and a color filter including the black matrix will be described, and a liquid crystal display device including such a color filter will be described as a specific example of the image display device.

### Black Matrix

It is also preferable that the cured film obtained by using the composition according to the embodiment of the present invention is included in a black matrix. The black matrix is incorporated into a color filter, a solid-state imaging element, and an image display device such as a liquid crystal display device in some cases.

Examples of the black matrix include those described above; a black rim provided in the peripheral portion of an image display device such as a liquid crystal display device; a lattice-like and/or stripe-like black portion between pixels of red, blue, and green; and a dot-like and/or linear black pattern for shielding a thin film transistor (TFT) from light. The definition of the black matrix is described in, for example, “Glossary of liquid crystal display manufacturing device”, written by Yasuhira KANNO, 2nd edition, NIKKAN KOGYO SHIMBUN, LTD., 1996, p. 64.

In order to improve the display contrast and to prevent image quality deterioration resulting from current leakage of light in a case of an active matrix driving-type liquid crystal display device using a thin film transistor (TFT), the black matrix preferably has high light shielding properties (the optical density OD is 3 or more).

The method for manufacturing the black matrix is not particularly limited, but the black matrix can be manufactured in the same manner as the method for manufacturing the cured film. Specifically, by applying the composition on a substrate to form a composition layer and performing exposure and development on the composition layer, a patterned cured film (black matrix) can be manufactured. The film thickness of the cured film used as the black matrix is preferably 0.1 to 4.0 µm.

The above-described substrate is not particularly limited, but preferably has a transmittance of 80% or more for visible light (wavelength of 400 to 800 nm). Examples of a material of such a base material include glass such as soda lime glass, alkali-free glass, quartz glass, and borosilicate glass, and plastic such as a polyester-based resin and a polyolefin-based resin, and from the viewpoints of chemical resistance and heat resistance, alkali-free glass, quartz glass, or the like is preferable.

### Color Filter

It is also preferable that the cured film obtained by using the composition according to the embodiment of the present invention is included in a color filter.

The aspect in which the color filter includes the cured film is not particularly limited, but examples thereof include a color filter comprising a substrate and the above-described black matrix. That is, examples thereof include a color filter comprising colored pixels of red, green, and blue which are formed in the opening portion of the black matrix formed on a substrate.

The color filter including a black matrix (cured film) can be manufactured, for example, by the following method.

First, in an opening portion of a patterned black matrix formed on a substrate, a coating film (composition layer) of a composition including each of pigments corresponding to the respective colored pixels of the color filter is formed. The composition for each color is not particularly limited, known compositions can be used, but in the composition described in the present specification, it is preferable that a composition in which the light shielding pigment is replaced with a colorant corresponding to each pixel is used.

Subsequently, the composition layer is subjected to exposure through a photo mask having a pattern corresponding to the opening portion of the black matrix. Next, colored pixels can be formed in the opening portion of the black matrix by removing a non-exposed portion by a development treatment, and then performing baking. In a case where the series of operations are performed using, for example, a composition for each color including red, green, and blue pigments, a color filter having red, green, and blue pixels can be manufactured.

### Liquid Crystal Display Device

It is also preferable that the cured film obtained by using the composition according to the embodiment of the present invention is included in a liquid crystal display device. The aspect in which the liquid crystal display device includes the cured film is not particularly limited, and examples thereof include an aspect in which the liquid crystal display device includes a color filter including the black matrix (cured film) described above.

Examples of the liquid crystal display device include an aspect in which the liquid crystal display device comprises a pair of substrates disposed to face each other and a liquid crystal compound sealed into the space between the substrates. The substrates are as described above as the substrate for a black matrix.

Examples of a specific aspect of the liquid crystal display device include a laminate having polarizing plate/substrate/color filter/transparent electrode layer/alignment film/liquid crystal layer/alignment film/transparent electrode layer/thin film transistor (TFT) element/substrate/polarizing plate/backlight unit in this order from the user side.

In addition, the liquid crystal display device is not limited to the above-described liquid crystal display devices, and examples thereof include the liquid crystal display devices described in “Electronic display device (written by Akio SASAKI, Kogyo Chosakai Publishing Co., Ltd., published in 1990)”, “Display Device (written by Sumiaki IBUKI, Sangyo Tosho Publishing Co., Ltd., published in 1989)”, or the like. In addition, examples thereof include the liquid crystal display device described in “Next-Generation Liquid Crystal Display Technology (edited by Tatsuo UCHIDA, Kogyo Chosakai Publishing Co., Ltd., published in 1994)”.

### Infrared Sensor

It is also preferable that the cured film obtained by using the composition according to the embodiment of the present invention is included in an infrared sensor.

Next, a solid-state imaging device to which the above-described infrared sensor is applied will be described.

The above-described solid-state imaging device includes a lens optical system, a solid-state imaging element, an infrared emission diode, and the like. Furthermore, regarding each of the configurations of the solid-state imaging device, reference can be made to paragraphs 0032 to 0036 of JP2011-233983A, the contents of which are incorporated into the specification of the present specification.

### EXAMPLES

Hereinafter, the present invention will be described in more detail based on Examples. The materials, the amounts of materials used, the proportions, the treatment details, the treatment procedure, and the like shown in Examples below may be appropriately modified as long as the modifications do not depart from the spirit of the present invention. Accordingly, the scope of the present invention is not limited to the following Examples.

### Preparation of Pigment Dispersion Liquid

A pigment dispersion liquid was prepared using the raw materials shown below.

### Raw Material for Pigment Dispersion Liquid

### Carbon Black

The following CB-1 to CB-6 were used as carbon black.
· CB-1: #2350 (average primary particle diameter: 15 nm, pH: 2.5, manufactured by Mitsubishi Chemical Corporation)
· CB-2: MA77 (average primary particle diameter: 23 nm, pH: 2.5, manufactured by Mitsubishi Chemical Corporation)
· CB-3: Raven1080 (average primary particle diameter: 28 nm, pH: 2.4, manufactured by Columbia Chemical)
· CB-4: MA220 (average primary particle diameter: 55 nm, pH: 3.0, manufactured by Mitsubishi Chemical Corporation)
· CB-5: #2600 (average primary particle diameter: 13 nm, pH: 6.5, manufactured by Mitsubishi Chemical Corporation)
· CB-6: PRINTEX 45 (average primary particle diameter: 26 nm, pH: 9.5, manufactured by Orion Engineered Carbons S.A.)

### Metal-Containing Particles (Nitride or Oxynitride)

The following P-1 to P-3 were used as metal-containing particles.
· P-1: 13 M-T (titanium oxynitride, manufactured by Mitsubishi Materials Corporation)
· P-2: titanium nitride particles (manufactured by Hefei Kai’er Nanometer Technology and Development Co., Ltd.)
· P-3: zirconium oxynitride particles (manufactured by Mitsubishi Materials Corporation)

### Barium Sulfate

The following BS-1 was used as barium sulfate.
· BS-1: BF-20 (manufactured by SAKAI CHEMICAL INDUSTRY CO., LTD.) (average particle diameter: 0.03 µm, pH: 10)

### Copper Phthalocyanines

The following CP-1 to CP-3 were used as copper phthalocyanines.
· CP-1: Pigment Blue 15 (copper phthalocyanine, manufactured by Tokyo Chemical Industry Co., Ltd.)
· CP-2: copper phthalocyanine-3,4′,4″,4‴-tetrasulfonic acid tetrasodium salt (copper phthalocyanine derivative, manufactured by Sigma-Aldrich Co., LLC)
· CP-3: Solsperse 5000 (copper phthalocyanine derivative, manufactured by Lubrizol Limited)
The “CP-3 (Solsperse 5000)” corresponds to a salt composed of copper phthalocyanine having a sulfonic acid group and dimethyldioctadecylammonium.

### Dispersant (Resin)

As a dispersant, dispersants H-1 to H-5 having the following structures were used. A numerical value described in each structural unit included in a main chain means % by mole of each structural unit with respect to all structural units. A numerical value described in each structural unit included in a side chain indicates a repetition number.
· H-1: dispersant having the following structure (acid value = 103 mgKOH/g, amine value = 103 mgKOH/g, weight-average molecular weight = 13,000)

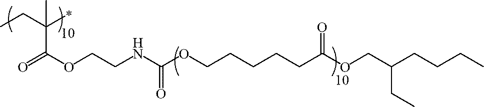

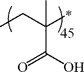

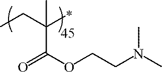

· H-2: dispersant having the following structure (acid value = 58 mgKOH/g, weight-average molecular weight = 32,000)

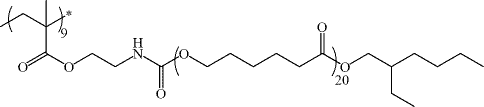

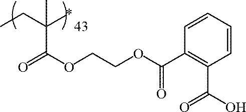

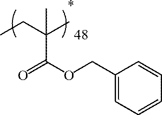

· H-3: dispersant having the following structure (acid value = 33 mgKOH/g, amine value = 44 mgKOH/g, weight-average molecular weight = 23,000)

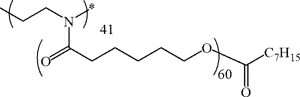

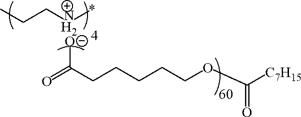

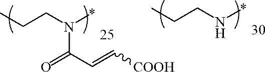

· H-4: Disperbyk167 (manufactured by BYK-Chemie GmbH; amine value = 13 mgKOH/g)
· H-5: Disperbyk161 (manufactured by BYK-Chemie GmbH, amine value = 11 mgKOH/g)

### Solvent

· Propylene glycol monomethyl ether acetate (PGMEA)
· Butyl acetate
· Cyclopentanone

### Preparation of Pigment Dispersion Liquid

First, each component in Table 1 was mixed at formulated amounts shown in Table 1 for 15 minutes with a stirrer (EUROSTAR manufactured by IKA Works GmbH & Co. KG) to obtain a mixed solution. Next, the obtained mixed solution was subjected to a dispersion treatment using NPM-Pilot manufactured by Shinmaru Enterprises Corporation under the following conditions to obtain a pigment dispersion liquid.

### Dispersion Conditions

· Bead size: φ 0.05 mm, (zirconia beads manufactured by NIKKATO CORPORATION, YTZ)
· Bead filling rate: 65% by volume
· Circumferential speed of mill: 10 m/sec
· Circumferential speed of separator: 13 m/s
· Amount of mixed solution subjected to dispersion treatment: 15 kg
· Circulation flow rate (pump supply rate): 90 kg/hour
· Temperature of treatment liquid: 19° C. to 21° C.
· Coolant: water
· Treatment time: about 22 hours

The compositions of the pigment dispersion liquids are shown in Table 1 below.

TABLE 1

| | Carbon black or metal-containing particles | | Barium sulfate | | Copper phthalocyanines A | | Dispersant | | Solvent | |
|---|---|---|---|---|---|---|---|---|---|---|
| | Type | Addition amount (part by mass) | Type | Addition amount (part by mass) | Type | Addition amount (part by mass) | Type | Addition amount (part by mass) | Type | Addition amount (part by mass) |
| Dispersion liquid 1 | CB-1 | 18.0 | BS-1 | 2.0 | CP-1 | 1.0 | H-1 | 5.0 | PGMEA | 74.0 |
| Dispersion liquid 2 | CB-1 | 18.0 | BS-1 | 2.0 | CP-2 | 1.0 | H-1 | 5.0 | PGMEA | 74.0 |
| Dispersion liquid 3 | CB-1 | 18.0 | BS-1 | 2.0 | CP-3 | 1.0 | H-1 | 5.0 | PGMEA | 74.0 |
| Dispersion liquid 4 | CB-1 | 18.0 | BS-1 | 2.0 | CP-3 | 1.0 | H-2 | 5.0 | PGMEA | 74.0 |
| Dispersion liquid 5 | CB-1 | 18.0 | BS-1 | 2.0 | CP-3 | 1.0 | H-3 | 5.0 | PGMEA | 74.0 |
| Dispersion liquid 6 | CB-1 | 18.0 | BS-1 | 2.0 | CP-3 | 1.0 | H-4 | 5.0 | PGMEA | 74.0 |
| Dispersion liquid 7 | CB-1 | 18.0 | BS-1 | 2.0 | CP-3 | 1.0 | H-5 | 5.0 | PGMEA | 74.0 |
| Dispersion liquid 8 | CB-1 | 19.8 | BS-1 | 0.2 | CP-3 | 1.0 | H-3 | 5.0 | PGMEA | 74.0 |
| Dispersion liquid 9 | CB-1 | 19.5 | BS-1 | 0.5 | CP-3 | 1.0 | H-3 | 5.0 | PGMEA | 74.0 |
| Dispersion liquid 10 | CB-1 | 15.0 | BS-1 | 5.0 | CP-3 | 1.0 | H-3 | 5.0 | PGMEA | 74.0 |
| Dispersion liquid 11 | CB-1 | 13.0 | BS-1 | 7.0 | CP-3 | 1.0 | H-3 | 5.0 | PGMEA | 74.0 |
| Dispersion liquid 12 | CB-2 | 18.0 | BS-1 | 2.0 | CP-3 | 1.0 | H-4 | 5.0 | PGMEA | 74.0 |
| Dispersion liquid 13 | CB-3 | 18.0 | BS-1 | 2.0 | CP-3 | 1.0 | H-4 | 5.0 | PGMEA | 74.0 |
| Dispersion liquid 14 | CB-4 | 18.0 | BS-1 | 2.0 | CP-3 | 1.0 | H-4 | 5.0 | PGMEA | 74.0 |
| Dispersion liquid 15 | CB-5 | 18.0 | BS-1 | 2.0 | CP-3 | 1.0 | H-4 | 5.0 | PGMEA | 74.0 |
| Dispersion liquid 16 | CB-6 | 18.0 | BS-1 | 2.0 | CP-3 | 1.0 | H-4 | 5.0 | PGMEA | 74.0 |
| Dispersion liquid 17 | CB-1 | 18.0 | BS-1 | 2.0 | CP-3 | 1.0 | H-3 | 5.0 | PGMEA Butyl acetate | 60 10.8 |
| Dispersion liquid 18 | CB-1 | 18.0 | BS-S | 2.0 | CP-3 | 1.0 | H-3 | 5.0 | PGMEA Butyl acetate | 35.4 35.4 |
| Dispersion liquid 19 | CB-1 | 18.0 | BS-1 | 2.0 | CP-3 | 1.0 | H-3 | 5.0 | PGMEA Cyclopentanone | 60 10.8 |
| Dispersion liquid 20 | CB-3 | 18.0 | BS-1 | 2.0 | | 0.0 | H-4 | 6.0 | PGMEA | 74.0 |
| Comparative dispersion liquid 1 | CB-6 | 20.0 | | 0.0 | CP-3 | 1.0 | H-5 | 5.0 | PGMEA | 74.0 |
| Comparative dispersion liquid 2 | CB-3 | 20.0 | | 0.0 | CP-3 | 1.0 | H-4 | 5.0 | PGMEA | 74.0 |
| Dispersion liquid 21 | P-1 | 15.6 | | 0.0 | | 0.0 | H-3 | 9.7 | PGMEA | 74.7 |
| Dispersion liquid 22 | P-2 | 15.6 | | 0.0 | | 0.0 | H-3 | 9.7 | PGMEA | 74.7 |
| Dispersion liquid 23 | P-3 | 15.6 | | 0.0 | | 0.0 | H-3 | 9.7 | PGMEA | 74.7 |
| Dispersion liquid 24 | P-1 | 24.4 | | 0.0 | | 0.0 | H-2 | 7.3 | PGMEA Butyl acetate | 41.0 27.3 |

### Preparation of Composition

A composition was prepared using the raw materials shown below.

### Raw Materials for Composition

### Pigment Dispersion Liquid

As a pigment dispersion liquid, the pigment dispersion liquids (dispersion liquids 1 to 23 and comparative dispersion liquids 1 and 2) prepared in the above part were used.

### Alkali-Soluble Resin

As an alkali-soluble resin, the following resins C-1 to C-16 were used. Structures of the resins C-1 to C-16 are shown below. A numerical value described in each structural unit means % by mole of each structural unit with respect to all structural units.
· C-1: resin having the following structure (acid value = 70 mgKOH/g, weight-average molecular weight = 11,000)

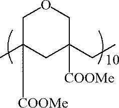

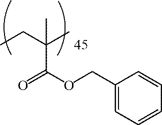

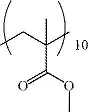

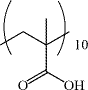

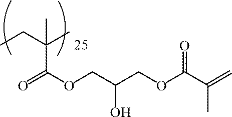

· C-2: resin having the following structure (acid value = 110 mgKOH/g, weight-average molecular weight = 33,000)

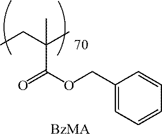

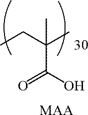

· As an alkali-soluble resin, the following resin C-3 was synthesized as follows.

Methyl methacrylate (173.7 g), methacrylic acid (20.0 g), and 2-hydroxyethyl methacrylate (6.3 g) were mixed to prepare a raw material monomer solution. In addition, a thermal polymerization initiator (V-601 manufactured by Wako Pure Chemical Industries, Ltd.) in an amount of 2 mol% with respect to the total mass of the above-described raw material monomer and 1-methoxy-2-propanol in an amount of 111% by mass with respect to the total mass of the above-described raw material monomer were mixed to prepare a mixed solution. The mixed solution was added dropwise to 1-methoxy-2-propanol, which had been heated to 80° C., in an amount of 74% by mass with respect to the total mass of the above-described raw material monomer over 2 hours (dropwise polymerization), and the mixture was heated at 80° C. for 2 hours and further heated at 90° C. for 3 hours. The obtained resin solution was dropwise to a place where 1000 g of water was continuously stirred, and the suspension was collected by filtration to synthesize a resin C-3.

### Synthesis of Resins C-4 to C-16

An alkali-soluble resin having units shown in Table 2 below was synthesized in the same manner as in the resin C-3.

“Copolymerization component species” in Table 2 indicates the types of units 1 to 4 included in each polymer.

“Copolymerization component ratio (% by mass)” in Table 2 indicates the content (% by mass) of each of the units 1 to 4 with respect to all repeating units of the polymer.

TABLE 2

| Polymer | Copolymerization component species | | | | Copolymerization component ratio (% by mass) | | | | Mw | Acid value [mgKOH/g] |
|---|---|---|---|---|---|---|---|---|---|---|
| | Unit 1 | Unit 2 | Unit 3 | Unit 4 | Unit 1 | Unit 2 | Unit 3 | Unit 4 | | |
| C-3 | A-1 | B-1 | A-7 | - | 86.85 | 10 | 3.15 | - | 18400 | 61.2 |
| C-4 | A-1 | B-1 | - | - | 87.5 | 12.5 | - | - | 19500 | 75.9 |
| C-5 | A-1 | B-1 | A-3 | A-7 | 80.05 | 10 | 6.8 | 3.15 | 19900 | 61.3 |
| C-6 | A-2 | B-1 | A-6 | - | 78.00 | 10.00 | 12.00 | - | 21900 | 64.9 |
| C-7 | A-3 | B-1 | A-6 | - | 80.75 | 7.5 | 11.75 | - | 24100 | 48.9 |
| C-8 | A-3 | B-1 | A-7 | - | 86.85 | 10 | 3.15 | - | 24600 | 65.3 |
| C-9 | A-4 | B-3 | - | - | 82.8 | 17.2 | - | - | 28700 | 63.9 |
| C-10 | A-5 | B-2 | A-8 | - | 78.6 | 10 | 11.4 | - | 27900 | 78.2 |
| C-11 | A-10 | B-2 | A-9 | - | 82.5 | 6.35 | 11.15 | - | 12600 | 49.3 |
| C-12 | A-11 | B-4 | A-6 | - | 40.5 | 50 | 9.5 | - | 23300 | 85.2 |
| C-13 | A-1 | B-1 | C-1 | - | 61.3 | 12.5 | 26.2 | - | 16340 | 72.4 |
| C-14 | A-1 | B-1 | C-5 | - | 74.7 | 12.5 | 12.8 | - | 19514 | 73.0 |
| C-15 | A-2 | B-4 | C-2 | C-3 | 35 | 46.5 | 12.5 | 6 | 17300 | 80.4 |
| C-16 | A-3 | B-3 | C-4 | - | 78.5 | 12 | 9.5 | - | 23600 | 45.8 |

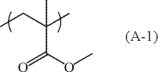

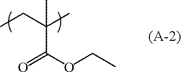

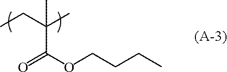

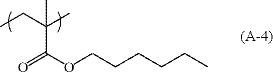

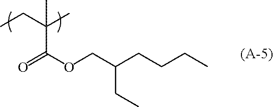

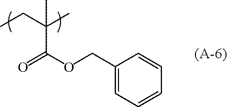

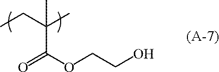

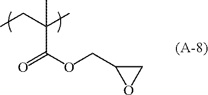

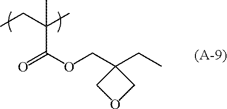

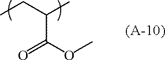

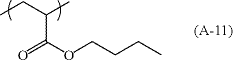

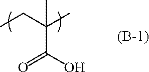

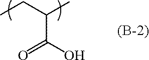

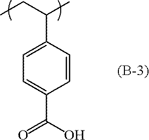

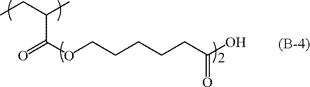

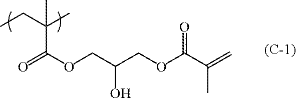

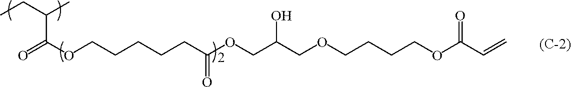

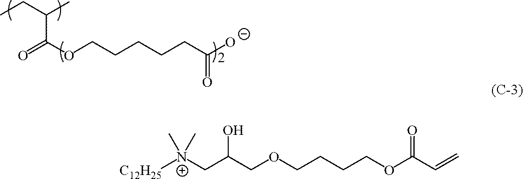

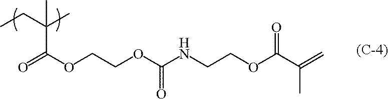

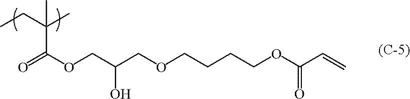

### First Polymerizable Compound

As a first polymerizable compound, the following D-1-2 to D-1-6 were used. D-1-1 corresponds to a mixture including the first polymerizable compound and the second polymerizable compound.
· D-1-1: VISCOAT #802 (manufactured by OSAKA ORGANIC CHEMICAL INDUSTRY LTD.; octafunctional acrylate including hexafunctional and decafunctional)
· D-1-2: CN9013 (manufactured by Sartomer; nonafunctional monomer)
· D-1-3: CN2304 (manufactured by Sartomer; octadecafunctional monomer)
· D-1-4: UA-306H (manufactured by KYOEISHA CHEMICAL Co., LTD.; decafunctional monomer)
· D-1-5: compound having the following structure

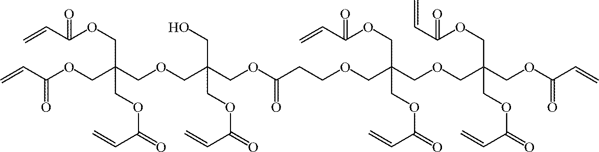 [SMILES: C=CC(=O)OCC(COCCC(=O)OCC(CO)(COCC(COC(=O)C=C)(COC(=O)C=C)COC(=O)C=C)COC(=O)C=C)(COCC(COC(=O)C=C)(COC(=O)C=C)COC(=O)C=C)COC(=O)C=C]

· D-1-6: compound having the following structure

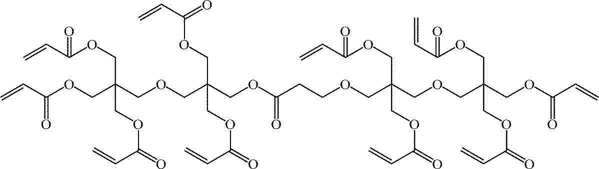 [SMILES: C=CC(=O)OCC(COCCC(=O)OCC(COCC(COC(=O)C=C)(COC(=O)C=C)COC(=O)C=C)(COC(=O)C=C)COC(=O)C=C)(COCC(COC(=O)C=C)(COC(=O)C=C)COC(=O)C=C)COC(=O)C=C]

### Second Polymerizable Compound

As a second polymerizable compound, the following D-2-1 to D-2-3 were used.
· D-2-1: compound having the following structure

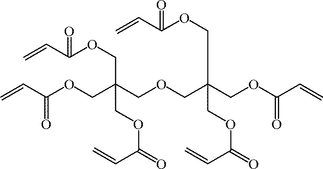 [SMILES: C=CC(=O)OCC(COCC(COC(=O)C=C)(COC(=O)C=C)COC(=O)C=C)(COC(=O)C=C)COC(=O)C=C]

· D-2-2: NK ESTER A-TMMT (manufactured by Shin-Nakamura Chemical Co., Ltd., 4-functional monomer)
· D-2-3: ARONIX M-309 (manufactured by TOAGOSEI CO., LTD., 3-functional monomer)

### Polymerization Initiator

As a polymerization initiator, the following E-1 to E-10 were used.
· E-1: IRGACURE OXE01 (manufactured by BASF SE, oxime ester-based polymerization initiator)
· E-2: IRGACURE OXE02 (manufactured by BASF SE, oxime ester-based polymerization initiator)
· E-3: oxime ester-based polymerization initiator (structural formula shown below)

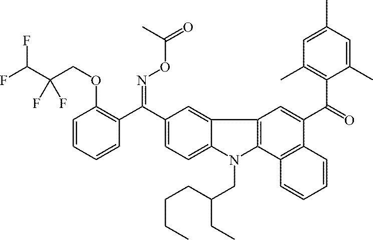 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

· E-4: oxime ester-based polymerization initiator (structural formula shown below)

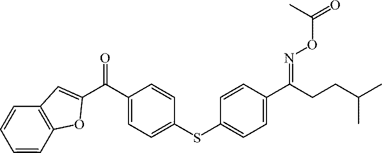 [SMILES: CC(=O)O/N=C(\CCC(C)C)c1ccc(Sc2ccc(C(=O)c3cc4ccccc4o3)cc2)cc1]

· E-5: NCI-831 (manufactured by ADEKA CORPORATION, oxime ester-based polymerization initiator)
· E-6: compound having the following structure (corresponding to the compound represented by Formula (1) described above, oxime ester-based polymerization initiator)

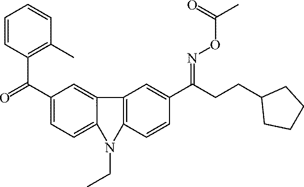 [SMILES: CCn1c2ccc(C(=O)c3ccccc3C)cc2c2cc(/C(CCC3CCCC3)=N/OC(C)=O)ccc21]

· E-7: IRGACURE 379 (manufactured by BASF SE, non-oxime ester-based polymerization initiator)
· E-8: NCI-730 (manufactured by ADEKA CORPORATION, oxime ester-based polymerization initiator)
· E-9: compound having the following structure (oxime ester-based polymerization initiator)

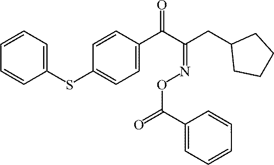 [SMILES: O=C(O/N=C(/CC1CCCC1)C(=O)c1ccc(Sc2ccccc2)cc1)c1ccccc1]

· E-10: Omnirad 1316 (IGM Resins B.V.; oxime ester-based polymerization initiator)

### Silica

As a silica, the following S-1 to S-5 were used.
· S-1: IPA-ST (isopropyl alcohol-dispersed silica sol manufactured by Nissan Chemical Corporation; average particle diameter: 12 nm, solid content: 30% by mass)
· S-2: IPA-ST-L (isopropyl alcohol-dispersed silica sol manufactured by Nissan Chemical Corporation; average particle diameter: 45 nm, solid content: 30% by mass)
· S-3: IPA-ST-ZL (isopropyl alcohol-dispersed silica sol manufactured by Nissan Chemical Corporation; average particle diameter: 80 nm, solid content: 30% by mass)
· S-4: QSG-170 (silica sol manufactured by Shin-Etsu Chemical Co., Ltd.; average particle diameter: 170 nm, solid content: 100% by mass)
· S-5: MEK-AC-2140Z (methyl ethyl ketone-dispersed silica sol manufactured by Nissan Chemical Corporation; average particle diameter: 12 nm, solid content: 45% by mass)

### Solvent

· Propylene glycol monomethyl ether acetate (PGMEA)

### Adhesive

The following G-1 was used as an adhesive.
· G-1: EHPE 3150 (manufactured by DAICEL CORPORATION) (epoxy group-containing compound)

### Surfactant

The following W-1 to W-4 were used as a surfactant.
· W-1: KF-6000 (silicone-based surfactant (carbinol-modified silicone; dimethyl type), manufactured by Shin-Etsu Chemical Co., Ltd.)
· W-2: Dowsil SH-8400 Fluid (silicone-based surfactant (EO-modified silicone; dimethyl type), manufactured by Dow Chemical Company)
· W-3: KP323 (silicone-based surfactant (phenyl-modified silicone), manufactured by Shin-Etsu Chemical Co., Ltd.)
· W-4: FTERGENT 601AD (fluorine-based surfactant, NEOS COMPANY LIMITED)

### Preparation of Composition

Each component of Tables 3 to 6 was mixed with the pigment dispersion liquid shown in Table 1 in a formulated amount shown in Tables 3 to 6 to obtain each composition of Examples and Comparative Examples.

Compositions of the obtained compositions are shown in Tables 3 to 6.

TABLE 3

| | Pigment dispersion liquid | | Pigment dispersion liquid | | Alkali-soluble resin | | Polymerizable compound | | Polymerization initiator | | Silica | | Solvent | | Adhesive | | Surfactant | |
|---|---|---|---|---|---|---|---|---|---|---|---|---|---|---|---|---|---|---|
| | Type | Part by mass | Type | Part by mass | Type | Part by mass | Type | Part by mass | Type | Part by mass | Type | Part by mass | Type | Part by mass | Type | Part by mass | Type | Part by mass |
| Example composition 1 | Dispersion liquid 5 | 54.1 | - | | C-1 | 4 | D-1-1 | 6 | E-6 | 2 | S-1 | 3 | PGMEA | 30.9 | - | | W-1 | 0.01 |
| Example composition 2 | Dispersion liquid 5 | 54.1 | - | | C-1 | 4 | D-1-2 | 6 | E-6 | 2 | S-1 | 3 | PGMEA | 30.9 | - | | W-1 | 0.01 |
| Example composition 3 | Dispersion liquid 5 | 54.1 | - | | C-1 | 4 | D-1-3 | 6 | E-6 | 2 | S-1 | 3 | PGMEA | 30.9 | - | | W-1 | 0.01 |
| Example composition 4 | Dispersion liquid 5 | 54.1 | - | | C-1 | 4 | D-1-4 | 6 | E-6 | 2 | S-1 | 3 | PGMEA | 30.9 | - | | W-1 | 0.01 |
| Example composition 5 | Dispersion liquid 5 | 54.1 | - | | C-1 | 4 | D-2-1 | 6 | E-6 | 2 | S-1 | 3 | PGMEA | 30.9 | - | | W-1 | 0.01 |
| Example composition 6 | Dispersion liquid 5 | 54.1 | - | | C-1 | 4 | D-2-2 | 6 | E-6 | 2 | S-1 | 3 | PGMEA | 30.9 | - | | W-1 | 0.01 |
| Example composition 7 | Dispersion liquid 5 | 54.1 | - | | C-1 | 4 | D-2-3 | 6 | E-6 | 2 | S-1 | 3 | PGMEA | 30.9 | - | | W-1 | 0.01 |
| Example composition 8 | Dispersion liquid 5 | 54.1 | - | | C-1 | 4 | D-1-5 D-1-6 D-2-1 | 0.5 0.5 5 | E-6 | 2 | S-1 | 3 | PGMEA | 30.9 | - | | W-1 | 0.01 |
| Example composition 9 | Dispersion liquid 5 | 54.1 | - | | C-1 | 4 | D-1-5 D-1-6 D-2-1 | 0.25 0.25 5.5 | E-6 | 2 | S-1 | 3 | PGMEA | 30.9 | - | | W-1 | 0.01 |
| Example composition 10 | Dispersion liquid 5 | 54.1 | - | | C-1 | 4 | D-1-1 D-2-2 | 2 4 | E-6 | 2 | S-1 | 3 | PGMEA | 30.9 | - | | W-1 | 0.01 |
| Example composition 11 | Dispersion liquid 5 | 54.1 | - | | C-1 | 4 | D-1-1 D-2-2 | 4 2 | E-6 | 2 | S-1 | 3 | PGMEA | 30.9 | - | | W-1 | 0.01 |
| Example composition 12 | Dispersion liquid 5 | 54.1 | - | | C-1 | 4 | D-1-1 D-2-2 | 2 4 | E-1 | 2 | S-1 | 3 | PGMEA | 30.9 | - | | W-1 | 0.01 |
| Example composition 13 | Dispersion liquid 5 | 54.1 | - | | C-1 | 4 | D-1-1 D-2-2 | 2 4 | E-2 | 2 | S-1 | 3 | PGMEA | 30.9 | - | | W-1 | 0.01 |
| Example composition 14 | Dispersion liquid 5 | 54.1 | - | | C-1 | 4 | D-1-1 D-2-2 | 2 4 | E-3 | 2 | S-1 | 3 | PGMEA | 30.9 | - | | W-1 | 0.01 |
| Example composition 15 | Dispersion liquid 5 | 54.1 | - | | C-1 | 4 | D-1-1 D-2-2 | 2 4 | E-4 | 2 | S-1 | 3 | PGMEA | 30.9 | - | | W-1 | 0.01 |
| Example composition 16 | Dispersion liquid 5 | 54.1 | - | | C-1 | 4 | D-1-1 D-2-2 | 2 4 | E-5 | 2 | S-1 | 3 | PGMEA | 30.9 | - | | W-1 | 0.01 |
| Example composition 17 | Dispersion liquid 5 | 54.1 | - | | C-1 | 4 | D-1-1 D-2-2 | 2 4 | E-7 | 2 | S-1 | 3 | PGMEA | 30.9 | - | | W-1 | 0.01 |
| Example composition is | Dispersion liquid 5 | 54.1 | - | | C-1 | 4 | D-1-1 D-2-2 | 2 4 | E-5 E-6 | 1 1 | S-1 | 3 | PGMEA | 30.9 | - | | W-1 | 0.01 |

TABLE 4

| | Pigment dispersion liquid | | Pigment dispersion liquid | | Alkali-soluble resin | | Polymerizable compound | | Polymerization initiator | | Silica | | Solvent | | Adhesive | | Surfactant | |
|---|---|---|---|---|---|---|---|---|---|---|---|---|---|---|---|---|---|---|
| | Type | Part by mass | Type | Part by mass | Type | Part by mass | Type | Part by mass | Type | Part by mass | Type | Part by mass | Type | Part by mass | Type | Part by mass | Type | Part by mass |
| Example composition 19 | Dispersion liquid 13 | 54.1 | - | | C-1 | 4 | D-2-1 | 6 | E-6 | 2 | S-1 | 3 | PGMEA | 30.9 | - | | W-1 | 0.01 |
| Example composition 20 | Dispersion liquid 13 | 54.1 | - | | C-1 | 4 | D-2-1 | 6 | E-6 | 2 | S-2 | 3 | PGMEA | 30.9 | - | | W-1 | 0.01 |
| Example composition 21 | Dispersion liquid 13 | 54.1 | - | | C-1 | 4 | D-2-1 | 6 | E-6 | 2 | S-3 | 3 | PGMEA | 30.9 | - | | W-1 | 0.01 |
| Example composition 22 | Dispersion liquid 13 | 54.1 | - | | C-1 | 4 | D-2-1 | 6 | E-6 | 2 | S-4 | 0.9 | PGMEA | 33.0 | - | | W-1 | 0.01 |
| Example composition 23 | Dispersion liquid 13 | 54.1 | - | | C-1 | 4 | D-2-1 | 6 | E-6 | 2 | S-5 | 3 | PGMEA | 30.9 | - | | W-1 | 0.01 |
| Example composition 24 | Dispersion liquid 1 | 54.1 | - | | C-1 | 4 | D-2-1 | 6 | E-6 | 2 | S-1 | 3 | PGMEA | 30.9 | - | | W-1 | 0.01 |
| Example composition 25 | Dispersion liquid 2 | 54.1 | - | | C-1 | 4 | D-2-1 | 6 | E-6 | 2 | S-1 | 3 | PGMEA | 30.9 | - | | W-1 | 0.01 |
| Example composition 26 | Dispersion liquid 3 | 54.1 | - | | C-1 | 4 | D-2-1 | 6 | E-6 | 2 | S-1 | 3 | PGMEA | 30.9 | - | | W-1 | 0.01 |
| Example composition 27 | Dispersion liquid 4 | 54.1 | - | | C-1 | 4 | D-2-1 | 6 | E-6 | 2 | S-1 | 3 | PGMEA | 30.9 | - | | W-1 | 0.01 |
| Example composition 28 | Dispersion liquid 5 | 54.1 | - | | C-1 | 4 | D-2-1 | 6 | E-6 | 2 | S-1 | 3 | PGMEA | 30.9 | - | | W-1 | 0.01 |
| Example composition 29 | Dispersion liquid 6 | 54.1 | - | | C-1 | 4 | D-2-1 | 6 | E-6 | 2 | S-1 | 3 | PGMEA | 30.9 | - | | W-1 | 0.01 |
| Example composition 30 | Dispersion liquid 7 | 54.1 | - | | C-1 | 4 | D-2-1 | 6 | E-6 | 2 | S-1 | 3 | PGMEA | 30.9 | - | | W-1 | 0.01 |
| Example composition 31 | Dispersion liquid 8 | 54.1 | - | | C-1 | 4 | D-2-1 | 6 | E-6 | 2 | S-1 | 3 | PGMEA | 30.9 | - | | W-1 | 0.01 |
| Example composition 32 | Dispersion liquid 9 | 54.1 | - | | C-1 | 4 | D-2-1 | 6 | E-6 | 2 | S-1 | 3 | PGMEA | 30.9 | - | | W-1 | 0.01 |
| Example composition 33 | Dispersion liquid 10 | 54.1 | - | | C-1 | 4 | D-2-1 | 6 | E-6 | 2 | S-1 | 3 | PGMEA | 30.9 | - | | W-1 | 0.01 |
| Example composition 34 | Dispersion liquid 11 | 54.1 | - | | C-1 | 4 | D-2-1 | 6 | E-6 | 2 | S-1 | 3 | PGMEA | 30.9 | - | | W-1 | 0.01 |
| Example composition 35 | Dispersion liquid 12 | 54.1 | - | | C-1 | 4 | D-2-1 | 6 | E-6 | 2 | S-1 | 3 | PGMEA | 30.9 | - | | W-1 | 0.01 |
| Example composition 36 | Dispersion liquid 13 | 54.1 | - | | C-1 | 4 | D-2-1 | 6 | E-6 | 2 | S-1 | 3 | PGMEA | 30.9 | - | | W-1 | 0.01 |
| Example composition 37 | Dispersion liquid 14 | 54.1 | - | | C-1 | 4 | D-2-1 | 6 | E-6 | 2 | S-1 | 3 | PGMEA | 30.9 | - | | W-1 | 0.01 |
| Example composition 38 | Dispersion liquid 15 | 54.1 | - | | C-1 | 4 | D-2-1 | 6 | E-6 | 2 | S-1 | 3 | PGMEA | 30.9 | - | | W-1 | 0.01 |
| Example composition 39 | Dispersion liquid 16 | 54.1 | - | | C-1 | 4 | D-2-1 | 6 | E-6 | 2 | S-1 | 3 | PGMEA | 30.9 | - | | W-1 | 0.01 |
| Example composition 40 | Dispersion liquid 17 | 54.1 | - | | C-1 | 4 | D-2-1 | 6 | E-6 | 2 | S-1 | 3 | PGMEA | 30.9 | - | | W-1 | 0.01 |
| Example composition 41 | Dispersion liquid 18 | 54.1 | - | | C-1 | 4 | D-2-1 | 6 | E-6 | 2 | S-1 | 3 | PGMEA | 30.9 | - | | W-1 | 0.01 |
| Example composition 42 | Dispersion liquid 19 | 54.1 | - | | C-1 | 4 | D-2-1 | 6 | E-6 | 2 | S-1 | 3 | PGMEA | 30.9 | - | | W-1 | 0.01 |
| Example composition 43 | Dispersion liquid 20 | 54.1 | - | | C-1 | 4 | D-2-1 | 6 | E-6 | 2 | S-1 | 3 | PGMEA | 30.9 | - | | W-1 | 0.01 |

TABLE 5

| | Pigment dispersion liquid | | Pigment dispersion liquid | | Alkali-soluble resin | | Polymerizable compound | | Polymerization initiator | | Silica | | Solvent | | Adhesive | | Surfactant | |
|---|---|---|---|---|---|---|---|---|---|---|---|---|---|---|---|---|---|---|
| | Type | Part by mass | Type | Part by mass | Type | Part by mass | Type | Part by mass | Type | Part by mass | Type | Part by mass | Type | Part by mass | Type | Part by mass | Type | Part by mass |
| Example composition 44 | Dispersion liquid 13 | 54.1 | - | | C-1 | 4 | D-2-1 | 6 | E-6 | 2 | S-1 | 3 | PGMEA | 30.9 | - | | W-2 | 0.01 |
| Example composition 45 | Dispersion liquid 13 | 54.1 | - | | C-1 | 4 | D-2-1 | 6 | E-6 | 2 | S-1 | 3 | PGMEA | 30.9 | - | | W-3 | 0.01 |
| Example composition 46 | Dispersion liquid 13 | 54.1 | - | | C-1 | 4 | D-2-1 | 6 | E-6 | 2 | S-1 | 3 | PGMEA | 30.9 | - | | W-4 | 0.01 |
| Example composition 47 | Dispersion liquid 13 | 54.1 | - | | C-1 | 4 | D-2-1 | 6 | E-6 | 2 | S-1 | 3 | PGMEA | 30.9 | - | | W-3 W-4 | 0.01 0.01 |
| Example composition 48 | Dispersion liquid 13 | 54.1 | - | | C-1 | 4 | D-2-1 | 7 | E-6 | 1 | S-1 | 3 | PGMEA | 30.9 | - | | W-1 | 0.01 |
| Example composition 49 | Dispersion liquid 13 | 54.1 | - | | C-1 | 4 | D-2-1 | 6.5 | E-6 | 1.5 | S-1 | 3 | PGMEA | 30.9 | - | | W-1 | 0.01 |
| Example composition 50 | Dispersion liquid 13 | 54.1 | - | | C-1 | 4 | D-2-1 | 5 | E-6 | 3 | S-1 | 3 | PGMEA | 30.9 | - | | W-1 | 0.01 |
| Example composition 51 | Dispersion liquid 13 | 63.7 | - | | C-1 | 1.5 | D-2-1 | 6 | E-6 | 2 | S-1 | 3 | PGMEA | 23.8 | - | | W-1 | 0.01 |
| Example composition 52 | Dispersion liquid 13 | 40 | - | | C-1 | 6 | D-2-1 | 6 | E-6 | 2 | S-1 | 3 | PGMEA | 43.0 | - | | W-1 | 0.01 |
| Example composition 53 | Dispersion liquid 13 | 54.1 | Dispersion liquid 21 | 9.6 | C-1 | 1.5 | D-2-1 | 6 | E-6 | 2 | S-1 | 3 | PGMEA | 23.8 | - | | W-1 | 0.01 |
| Example composition 54 | Dispersion liquid 13 | 32 | Dispersion liquid 21 | 31.7 | C-1 | 1.5 | D-2-1 | 6 | E-6 | 2 | S-1 | 3 | PGMEA | 23.8 | - | | W-1 | 0.01 |
| Example composition 55 | Dispersion liquid 13 | 54.1 | Dispersion liquid 22 | 9.6 | C-1 | 1.5 | D-2-1 | 6 | E-6 | 2 | S-1 | 3 | PGMEA | 23.8 | - | | W-1 | 0.01 |
| Example composition 56 | Dispersion liquid 13 | 54.1 | Dispersion liquid 23 | 9.6 | C-1 | 1.5 | D-2-1 | 6 | E-6 | 2 | S-1 | 3 | PGMEA | 23.8 | - | | W-1 | 0.01 |
| Example composition 57 | Dispersion liquid 13 | 54.1 | - | | C-1 | 3 | D-2-1 | 6 | E-6 | 2 | S-1 | 3 | PGMEA | 30.9 | G-1 | 1 | W-1 | 0.01 |
| Example composition 58 | Dispersion liquid 13 | 54.1 | - | | C-1 | 4.9 | D-2-1 | 6 | E-6 | 2 | S-1 | 0.1 | PGMEA | 32.9 | - | | W-1 | 0.01 |
| Example composition 59 | Dispersion liquid 13 | 54.1 | - | | C-1 | 4.6 | D-2-1 | 6 | E-6 | 2 | S-1 | 1 | PGMEA | 32.3 | - | | W-1 | 0.01 |
| Example composition 60 | Dispersion liquid 13 | 54.1 | - | | C-1 | 4.5 | D-2-1 | 6 | E-6 | 2 | S-1 | 1.5 | PGMEA | 31.9 | - | | W-1 | 0.01 |
| Example composition 61 | Dispersion liquid 13 | 54.1 | - | | C-1 | 3.4 | D-2-1 | 6 | E-6 | 2 | S-1 | 5 | PGMEA | 29.5 | - | | W-1 | 0.01 |
| Example composition 62 | Dispersion liquid 13 | 54.1 | - | | C-1 | 2.5 | D-2-1 | 6 | E-6 | 2 | S-1 | 8 | PGMEA | 27.4 | - | | W-1 | 0.01 |
| Example composition 63 | Dispersion liquid 13 | 54.1 | - | | C-1 | 1.9 | D-2-1 | 6 | E-6 | 2 | S-1 | 10 | PGMEA | 26.0 | - | | W-1 | 0.01 |
| Example composition 64 | Dispersion liquid 13 | 54.1 | - | | C-1 | 0.4 | D-2-1 | 6 | E-6 | 2 | S-1 | 15 | PGMEA | 22.5 | - | | W-1 | 0.01 |
| Example composition 65 | Dispersion liquid 13 | 32 | Dispersion liquid 21 | 31.7 | C-1 | 1.5 | D-2-1 | 6 | E-8 | 2 | S-1 | 3 | PGMEA | 23.8 | - | | W-1 | 0.01 |
| Example composition 66 | Dispersion liquid 13 | 32 | Dispersion liquid 21 | 31.7 | C-1 | 1.5 | D-2-1 | 6 | E-9 | 2 | S-1 | 3 | PGMEA | 23.8 | - | | W-1 | 0.01 |
| Example composition 67 | Dispersion liquid 13 | 32 | Dispersion liquid 21 | 31.7 | C-1 | 1.5 | D-2-1 | 6 | E-10 | 2 | S-1 | 3 | PGMEA | 23.8 | - | | W-1 | 0.01 |
| Example composition 68 | Dispersion liquid 13 | 32 | Dispersion liquid 21 | 31.7 | C-1 | 1.5 | D-2-1 | 6 | E-6 | 2 | S-1 S-2 | 2.5 0.5 | PGMEA | 23.8 | - | | W-1 | 0.01 |

TABLE 6

| | Pigment dispersion liquid | | Pigment dispersion liquid | | Alkali-soluble resin | | Polymerizable compound | | Polymerization initiator | | Silica | | Solvent | | Adhesive | | Surfactant | |
|---|---|---|---|---|---|---|---|---|---|---|---|---|---|---|---|---|---|---|
| | Type | Part by mass | Type | Part by mass | Type | Part by mass | Type | Part by mass | Type | Part by mass | Type | Part by mass | Type | Part by mass | Type | Part by mass | Type | Part by mass |
| Example composition 69 | Dispersion liquid 13 | 54.1 | - | | C-1 | 4 | D-2-1 | 6 | E-6 | 2 | S-1 | 3 | PGMEA Butyl acetate | 20 10.9 | - | | W-4 | 0.01 |
| Example composition 70 | Dispersion liquid 13 | 54.1 | - | | C-2 | 4 | D-2-1 | 6 | E-6 | 2 | S-1 | 3 | PGMEA Butyl acetate | 20 10.9 | - | | W-4 | 0.01 |
| Example composition 71 | Dispersion liquid 13 | 54.1 | - | | C-3 | 4 | D-2-1 | 6 | E-6 | 2 | S-1 | 3 | PGMEA Butyl acetate | 20 10.9 | - | | W-4 | 0.01 |
| Example composition 72 | Dispersion liquid 13 | 54.1 | - | | C-4 | 4 | D-2-1 | 6 | E-6 | 2 | S-1 | 3 | PGMEA Butyl acetate | 20 10.9 | - | | W-4 | 0.01 |
| Example composition 73 | Dispersion liquid 13 | 54.1 | - | | C-5 | 4 | D-2-1 | 6 | E-6 | 2 | S-1 | 3 | PGMEA Butyl acetate | 20 10.9 | - | | W-4 | 0.01 |
| Example composition 74 | Dispersion liquid 13 | 54.1 | - | | C-6 | 4 | D-2-1 | 6 | E-6 | 2 | S-1 | 3 | PGMEA Butyl acetate | 20 10.9 | - | | W-4 | 0.01 |
| Example composition 75 | Dispersion liquid 13 | 54.1 | - | | C-7 | 4 | D-2-1 | 6 | E-6 | 2 | S-1 | 3 | PGMEA Butyl acetate | 20 10.9 | - | | W-4 | 0.01 |
| Example composition 76 | Dispersion liquid 13 | 54.1 | - | | C-8 | 4 | D-2-1 | 6 | E-6 | 2 | S-1 | 3 | PGMEA Butyl acetate | 20 10.9 | - | | W-4 | 0.01 |
| Example composition 77 | Dispersion liquid 13 | 54.1 | - | | C-9 | 4 | D-2-1 | 6 | E-6 | 2 | S-1 | 3 | PGMEA Butyl acetate | 20 10.9 | - | | W-4 | 0.01 |
| Example composition 78 | Dispersion liquid 13 | 54.1 | - | | C-10 | 4 | D-2-1 | 6 | E-6 | 2 | S-1 | 3 | PGMEA Butyl acetate | 20 10.9 | - | | W-4 | 0.01 |
| Example composition 79 | Dispersion liquid 13 | 54.1 | - | | C-11 | 4 | D-2-1 | 6 | E-6 | 2 | S-1 | 3 | PGMEA Butyl acetate | 20 10.9 | - | | W-4 | 0.01 |
| Example composition 80 | Dispersion liquid 13 | 54.1 | - | | C-12 | 4 | D-2-1 | 6 | E-6 | 2 | S-1 | 3 | PGMEA Butyl acetate | 20 10.9 | - | | W-4 | 0.01 |
| Example composition 81 | Dispersion liquid 13 | 54.1 | - | | C-13 | 4 | D-2-1 | 6 | E-6 | 2 | S-1 | 3 | PGMEA Butyl acetate | 20 10.9 | - | | W-4 | 0.01 |
| Example composition 82 | Dispersion liquid 13 | 54.1 | - | | C-14 | 4 | D-2-1 | 6 | E-6 | 2 | S-1 | 3 | PGMEA Butyl acetate | 20 10.9 | - | | W-4 | 0.01 |
| Example composition 83 | Dispersion liquid 13 | 54.1 | - | | C-15 | 4 | D-2-1 | 6 | E-6 | 2 | S-1 | 3 | PGMEA Butyl acetate | 20 10.9 | - | | W-4 | 0.01 |
| Example composition 84 | Dispersion liquid 13 | 54.1 | - | | C-16 | 4 | D-2-1 | 6 | E-6 | 2 | S-1 | 3 | PGMEA Butyl acetate | 20 10.9 | - | | W-4 | 0.01 |
| Example composition 85 | Dispersion liquid 17 | 54.1 | - | | C-3 | 4 | D-2-1 | 6 | E-6 | 2 | S-1 | 3 | PGMEA | 30.9 | - | | W-4 | 0.01 |
| Comparative composition 1 | Comparative dispersion liquid 1 | 54.1 | - | | C-1 | 4 | D-1-1 | 6 | E-6 | 2 | S-1 | 6 | PGMEA | 27.9 | - | | W-1 | 0.01 |
| Comparative composition 2 | Comparative dispersion liquid 2 | 54.1 | - | | C-1 | 4 | D-1-1 | 6 | E-6 | 2 | S-1 | 6 | PGMEA | 27.9 | - | | W-1 | 0.01 |
| Comparative composition 3 | Dispersion liquid 11 | 54.1 | - | | C-1 | 6 | D-2-1 | 9 | E-2 | 3 | | | PGMEA | 27.9 | - | | W-1 | 0.01 |
| Comparative composition 4 | - | | - | | C-1 | 8 | D-2-1 | 13 | E-6 | 5 | S-1 | 3 | PGMEA | 71.0 | - | | W-1 | 0.01 |

### Evaluation

The following evaluations were performed using the obtained composition.

### Evaluation of OD Value and Reflectivity

### Production of Substrate with Cured Film

Each composition obtained above was applied to a glass substrate by a spin coating method to produce a coating film having a film thickness of 2.0 µm after exposure. Pre-baking was performed on the obtained coating film at 100° C. for 120 seconds, and then the entire surface of the substrate was exposed at an exposure amount of 1000 mJ/cm² with a high-pressure mercury lamp (lamp power of 50 mW/cm²) using UX-1000SM-EH04 (manufactured by Ushio Inc.). Next, the exposed substrate was post-baked at 220° C. for 300 seconds to obtain a substrate with a cured film (light shielding film).

### Measurement of OD Value (evaluation of Light Shielding Properties)

Regarding the substrate with a cured film, which was obtained in Production of substrate with cured film described above, a transmittance spectrum in a wavelength range of 400 to 700 nm was measured with a spectrophotometer U-4100 (manufactured by Hitachi High-Technologies Corporation) and an integrating spherical light-receiving unit.

An OD value was calculated according to the following expression from a value of a transmittance (%) at a wavelength showing the maximum transmittance, and evaluated according to the following evaluation standard.

OD = -log₁₀(transmittance/100)

### Evaluation Standard

“A”: OD value was 3.5 or more
“B”: OD value was 2.5 or more and less than 3.5
“C”: OD value was 1.0 or more and less than 2.5
“D”: OD value was less than 1.0

### Evaluation of Reflectivity

Regarding the substrate with a cured film, which was obtained in Production of substrate with cured film described above, light having a wavelength of 350 to 1200 nm was incident on the substrate at an incidence angle of 5° using a VAR unit of a spectrometer V7200 (trade name) manufactured by JASCO Corporation, and a reflectivity of each wavelength was evaluated from the obtained reflectivity spectrum.

Specifically, the evaluation was performed according to the following evaluation standard with, as a reference, the reflectivity of light having a wavelength which exhibits the maximum reflectivity in a wavelength range of 400 to 700 nm.

### Evaluation Standard

“A”: reflectivity was less than 1%
“B″: reflectivity was 1% or more and less than 2%
“C″: reflectivity was 2% or more and less than 4%
“D”: reflectivity was 4% or more

### Evaluation of Viscosity Stability Over Time

In each composition obtained above, the viscosity (mPa·s) of the composition before a static treatment was measured using RE-85L (manufactured by TOKI SANGYO CO., LTD.) under the measurement conditions shown below. After the above-described measurement, the composition was allowed to stand at 7° C. under the condition of shading for 360 days (static treatment), and then the viscosity (mPa·s) of the composition after the static treatment was measured using RE-85L (manufactured by TOKI SANGYO CO., LTD.) under the measurement conditions shown below.

### Viscosity Measurement Conditions

Viscosities of the compositions before and after the above-described static treatment were all measured in a laboratory where the temperature was controlled to 22 ± 5° C. and the humidity was controlled to 60 ± 20% in a state in which the temperature of the composition was adjusted to 25° C.

Viscosity stability over time was evaluated based on the following evaluation standard, with the rate of change in viscosity before and after the above-described static treatment as an evaluation reference.

### Evaluation Standard

“A”: rate of change in viscosity was less than 3%
“B″: rate of change in viscosity was 3% or more and less than 5%
“C″: rate of change in viscosity was 5% or more and less than 10%
“D”: rate of change in viscosity was 10% or more

### Evaluation of Change in Reflectivity Before and After Heat Resistance Test

The substrate with a cured film, which was obtained in Production of substrate with cured film described above, was allowed to stand in a high-temperature chamber set at 150° C. for 1000 hours (heat resistance test), and reflectivity of the film after the heat resistance test was measured in the same procedure as Evaluation of reflectivity.

An absolute value of a numerical value obtained by subtracting the value of the reflectivity after the heat resistance test from the value of the reflectivity before the heat resistance test was defined as a change width. An evaluation was performed based on the following evaluation standard, with the above-described change width of the reflectivity as an evaluation reference. It is determined that evaluations “A” to “C” have no problem in practical use.

### Evaluation Standard

“A”: change width of the reflectivity was less than 0.3%
“B″: change width of the reflectivity was 0.3% or more and less than 0.8%
“C″: change width of the reflectivity was 0.8% or more and less than 1.5%
“D”: change width of the reflectivity was 1.5% or more

### Evaluation of Scratch Resistance

Regarding the substrate with a cured film, which was obtained in Production of substrate with cured film described above, the cured film was evaluated for pencil hardness by the method described in JIS K5600-5-4.

### Evaluation Standard

A: pencil hardness was 5H or more
B: pencil hardness was 4H
C: pencil hardness was 3H
D: pencil hardness was 2H or less

### Results

The test results of the compositions used in the test are shown in Tables 7 and 8.

In Tables 7 and 8, the column of “CB/silica” indicates the mass ratio of the content of the carbon black to the content of the silica.

In Tables 7 and 8, the column of “Barium sulfate/silica” indicates the mass ratio of the content of the barium sulfate to the content of the silica.

TABLE 7

| | Type | CB/silica | Barium sulfate/silica | OD value | Reflectivity | Viscosity stability over time | Change in reflectivity | Scratch resistance |
|---|---|---|---|---|---|---|---|---|
| Example 1 | Example composition 1 | 10.8 | 1.2 | B | B | A | A | A |
| Example 2 | Example composition 2 | 10.8 | 1.2 | B | B | A | A | B |
| Example 3 | Example composition 3 | 10.8 | 1.2 | B | B | A | A | B |
| Example 4 | Example composition 4 | 10.8 | 1.2 | B | B | A | A | B |
| Example 5 | Example composition 5 | 10.8 | 1.2 | B | B | A | A | C |
| Example 6 | Example composition 6 | 10.8 | 1.2 | B | B | A | A | C |
| Example 7 | Example composition 7 | 10.8 | 1.2 | B | B | A | A | C |
| Example 8 | Example composition 8 | 10.8 | 1.2 | B | B | A | A | A |
| Example 9 | Example composition 9 | 10.8 | 1.2 | B | B | A | A | A |
| Example 10 | Example composition 10 | 10.8 | 1.2 | B | B | A | A | A |
| Example 11 | Example composition 11 | 10.8 | 1.2 | B | B | A | A | A |
| Example 12 | Example composition 12 | 10.8 | 1.2 | B | B | A | A | B |
| Example 13 | Example composition 13 | 10.8 | 1.2 | B | B | A | A | B |
| Example 14 | Example composition 14 | 10.8 | 1.2 | B | B | A | A | B |
| Example 15 | Example composition 15 | 10.8 | 1.2 | B | B | A | A | B |
| Example 16 | Example composition 16 | 10.8 | 1.2 | B | B | A | A | B |
| Example 17 | Example composition 17 | 10.8 | 1.2 | B | B | A | A | B |
| Example 18 | Example composition 18 | 10.8 | 1.2 | B | B | A | A | A |
| Example 19 | Example composition 19 | 10.8 | 1.2 | B | B | A | A | C |
| Example 20 | Example composition 20 | 10.8 | 1.2 | B | B | A | A | C |
| Example 21 | Example composition 21 | 10.8 | 1.2 | B | B | A | B | C |
| Example 22 | Example composition 22 | 10.8 | 1.2 | B | B | A | C | C |
| Example 23 | Example composition 23 | 10.8 | 1.2 | B | B | A | A | C |
| Example 24 | Example composition 24 | 10.8 | 1.2 | B | B | B | A | C |
| Example 25 | Example composition 25 | 10.8 | 1.2 | B | B | B | A | C |
| Example 26 | Example composition 26 | 10.8 | 1.2 | B | B | A | A | C |
| Example 27 | Example composition 27 | 10.8 | 1.2 | B | B | A | A | C |
| Example 28 | Example composition 28 | 10.8 | 1.2 | B | B | A | A | C |
| Example 29 | Example composition 29 | 10.8 | 1.2 | B | B | A | A | C |
| Example 30 | Example composition 30 | 10.8 | 1.2 | B | B | A | A | C |
| Example 31 | Example composition 31 | 11.9 | 0.1 | B | C | B | A | C |
| Example 32 | Example composition 32 | 11.7 | 0.3 | B | B | A | A | C |
| Example 33 | Example composition 33 | 9.0 | 3.0 | B | B | A | A | C |
| Example 34 | Example composition 34 | 7.8 | 4.2 | C | B | B | A | C |
| Example 35 | Example composition 35 | 10.8 | 1.2 | B | B | A | A | C |
| Example 36 | Example composition 36 | 10.8 | 1.2 | B | B | A | A | C |
| Example 37 | Example composition 37 | 10.8 | 1.2 | B | B | A | A | C |
| Example 38 | Example composition 38 | 10.8 | 1.2 | B | B | A | A | C |
| Example 39 | Example composition 39 | 10.8 | 1.2 | B | B | A | A | C |
| Example 40 | Example composition 40 | 10.8 | 1.2 | B | B | A | A | C |
| Example 41 | Example composition 41 | 10.8 | 1.2 | B | B | A | A | C |
| Example 42 | Example composition 42 | 10.8 | 1.2 | B | B | A | A | C |
| Example 43 | Example composition 43 | 10.8 | 1.2 | B | B | C | A | C |
| Example 44 | Example composition 44 | 10.8 | 1.2 | B | B | A | A | C |
| Example 45 | Example composition 45 | 10.8 | 1.2 | B | B | A | A | B |

TABLE 8

| | | | | | | | | |
|---|---|---|---|---|---|---|---|---|
| | Type | CB/silica | Barium sulfate/silica | OD value | Reflectivity | Viscosity stability over time | Change in reflectivity | Scratch resistance |
| Example 46 | Example composition 46 | 10.8 | 1.2 | B | B | A | B | C |
| Example 47 | Example composition 47 | 10.8 | 1.2 | B | B | A | A | B |
| Example 48 | Example composition 48 | 10.8 | 1.2 | B | B | A | A | C |
| Example 49 | Example composition 49 | 10.8 | 1.2 | B | B | A | A | C |
| Example 50 | Example composition 50 | 10.8 | 1.2 | B | B | A | A | C |
| Example 51 | Example composition 51 | 12.7 | 1.4 | A | B | A | A | C |
| Example 52 | Example composition 52 | 8.0 | 0.9 | C | B | A | A | C |
| Example 53 | Example composition 53 | 10.8 | 1.2 | A | B | A | A | C |
| Example 54 | Example composition 54 | 6.4 | 0.7 | A | B | A | A | C |
| Example 55 | Example composition 55 | 10.8 | 1.2 | A | B | A | A | C |
| Example 56 | Example composition 56 | 10.8 | 1.2 | A | B | A | A | C |
| Example 57 | Example composition 57 | 10.8 | 1.2 | B | B | A | A | B |
| Example 58 | Example composition 58 | 324.6 | 36.1 | B | C | A | C | C |
| Example 59 | Example composition 59 | 32.5 | 3.6 | B | C | A | B | C |
| Example 60 | Example composition 60 | 21.6 | 2.4 | B | B | A | A | C |
| Example 61 | Example composition 61 | 6.5 | 0.7 | B | B | A | A | C |
| Example 62 | Example composition 62 | 4.1 | 0.5 | B | B | A | A | C |
| Example 63 | Example composition 63 | 3.2 | 0.4 | B | B | B | A | C |
| Example 64 | Example composition 64 | 2.2 | 0.2 | B | B | C | A | C |
| Example 65 | Example composition 65 | 6.4 | 0.7 | A | B | A | A | C |
| Example 66 | Example composition 66 | 6.4 | 0.7 | A | B | A | A | C |
| Example 67 | Example composition 67 | 6.4 | 0.7 | A | B | A | A | C |
| Example 68 | Example composition 68 | 6.4 | 0.7 | A | B | A | A | C |
| Example 69 | Example composition 69 | 10.8 | 1.2 | B | B | A | A | C |
| Example 70 | Example composition 70 | 10.8 | 1.2 | B | B | A | A | C |
| Example 71 | Example composition 71 | 10.8 | 1.2 | B | A | A | A | C |
| Example 72 | Example composition 72 | 10.8 | 1.2 | B | A | A | A | C |
| Example 73 | Example composition 73 | 10.8 | 1.2 | B | A | A | A | C |
| Example 74 | Example composition 74 | 10.8 | 1.2 | B | A | A | A | C |
| Example 75 | Example composition 75 | 10.8 | 1.2 | B | A | A | A | C |
| Example 76 | Example composition 76 | 10.8 | 1.2 | B | A | A | A | C |
| Example 77 | Example composition 77 | 10.8 | 1.2 | B | A | A | A | C |
| Example 78 | Example composition 78 | 10.8 | 1.2 | B | A | A | A | B |
| Example 79 | Example composition 79 | 10.8 | 1.2 | B | A | A | A | B |
| Example 80 | Example composition 80 | 10.8 | 1.2 | B | A | A | A | C |
| Example 81 | Example composition 81 | 10.8 | 1.2 | B | A | A | A | B |
| Example 82 | Example composition 82 | 10.8 | 1.2 | B | A | A | A | B |
| Example 83 | Example composition 83 | 10.8 | 1.2 | B | A | A | A | B |
| Example 84 | Example composition 84 | 10.8 | 1.2 | B | A | A | A | B |
| Example 85 | Example composition 85 | 10.8 | 1.2 | B | A | A | A | C |
| Comparative Example 1 | Comparative composition 1 | 6.0 | 0.0 | B | D | D | D | C |
| Comparative Example 2 | Comparative composition 2 | 6.0 | 0.0 | B | D | D | D | C |
| Comparative Example 3 | Comparative composition 3 | – | – | B | D | B | D | D |
| Comparative Example 4 | Comparative composition 4 | – | – | D | C | A | A | C |

From the results of Tables 7 and 8, it was confirmed that the cured film produced by the compositions of Examples had excellent light shielding properties and that the change in reflectivity of the cured film before and after the heat resistance test was small.

From the comparison of Examples 1 to 4 and Examples 8 to 11, and Examples 5 to 7, it was confirmed that, in a case where the first polymerizable compound was included in the polymerizable compound, the scratch resistance was more excellent.

Furthermore, from the comparison of Examples 1 to 7 and Examples 8 to 11, it was confirmed that, in a case where the mass ratio of the content of the second polymerizable compound to the content of the first polymerizable compound was 30/70 to 95/5, the scratch resistance was even more excellent.

From the comparison of Examples 12 to 17 and Example 11, it was confirmed that, in a case where the polymerization initiator is the above-described compound represented by Formula (1), the scratch resistance was more excellent.

From the comparison of Examples 19 to 22, it was confirmed that, in a case where the average particle diameter of the silica was in a range of 5 to 100 nm (preferably, 10 to 50 nm), the change in reflectivity before and after the heat resistance test was smaller.

From the comparison of Example 19 and Example 43, it was confirmed that, in a case where the composition includes the copper phthalocyanines, the viscosity stability over time was more excellent.

Furthermore, from the comparison of Examples 24 and 25, and Example 26, it was confirmed that, in a case where the copper phthalocyanines was a salt composed of copper phthalocyanine having a sulfonic acid group and dimethyldioctadecylammonium, the viscosity stability over time was even more excellent.

From the comparison of Examples 28, 32, and 33, and Example 31, it was confirmed that, in a case where the mass ratio of the content of the barium sulfate to the content of the silica was 0.25 or more, the reflectivity or the viscosity stability over time was more excellent.

From the comparison of Examples 28, 32, and 33, and Example 34, it was confirmed that, in a case where the mass ratio of the content of the barium sulfate to the content of the silica was 4.0 or less, the light shielding properties or the viscosity stability over time was more excellent.

From the comparison of Example 45 and Examples 36 and 44, it was confirmed that, in a case where the silicone-based surfactant had a phenyl group, the scratch resistance was more excellent. In addition, from the comparison of Examples 36, 44, and 35, and Example 46, it was confirmed that, in a case where the surfactant was the silicone-based surfactant, the change in reflectivity before and after the heat resistance test was more excellent.

From the comparison of Example 59 and Example 58, it was confirmed that, in a case where the mass ratio of the content of the carbon black to the content of the silica was 99 or less, the reflectivity and the change in reflectivity before and after the heat resistance test were more excellent.

Furthermore, from the comparison of Examples 36 and 60 to 62, and Example 59, it was confirmed that, in a case where the mass ratio of the content of the carbon black to the content of the silica was 30 or less, the reflectivity and the change in reflectivity before and after the heat resistance test were even more excellent.

From the comparison of Example 63 and Example 64, it was confirmed that, in a case where the mass ratio of the content of the carbon black to the content of the silica was 3.0 or more, the viscosity stability over time was more excellent.

Furthermore, from the comparison of Examples 36 and 60 to 62, and Example 63, it was confirmed that, in a case where the mass ratio of the content of the carbon black to the content of the silica was 4.0 or more, the viscosity stability over time was even more excellent.

From the comparison of Example 36 and Example 52, it was confirmed that, in a case where the content of the carbon black in the composition according to the embodiment of the present invention was 30% by mass or more with respect to the total solid content of the composition, the light shielding properties were more excellent.

From the comparison of Examples 71 to 84 and Examples 1, 69, and 70, it was confirmed that, in a case where the alkali-soluble resin in the composition according to the embodiment of the present invention had a specific structure, the reflectivity was more excellent.

This is because the alkali-soluble resin having a specific structure causes phase separation to form an uneven structure having a period of several µm on the surface.

### Preparation of Light Shielding Composition A

The dispersion liquid 24 (57.8 parts by mass), the resin C-8 (6.9 parts by mass), D-2-1 (7.8 parts by mass) as the polymerizable compound, E-1 (1.1 parts by mass) and E-5 (1.1 parts by mass) as the polymerization initiator, cyclopentanone (11.6 parts by mass), propylene glycol monomethyl ether (10 parts by mass), and PGMEA (3.6 parts by mass) as the solvent, and W-1 (0.02 parts by mass) as the surfactant were mixed to produce a light shielding composition A.

### Production of Glass with Light Shielding Pattern and Black Matrix

The light shielding composition A was applied onto a 10 cm square glass substrate by a spin coating method to produce a coating film having a film thickness of 5.0 µm after exposure. Pre-baking was performed on the obtained coating film at 90° C. for 120 seconds, and then the coating film was exposed at an exposure amount of 200 mJ/cm² with a high-pressure mercury lamp (lamp power of 20 mW/cm²) using EVG610 (manufactured by EV Group) through a mask which could form a frame-like pattern with an outer dimension of 10 mm, an inner dimension of 9.5 mm, and a width of 0.5 mm. Puddle development was performed at 23° C. for 60 seconds using a 0.3% by mass of tetramethylammonium hydroxide (TMAH) aqueous solution. Thereafter, rinsing was performed by a spin shower using pure water. Next, a frame-like pattern was formed by heating (post-baking) at 200° C. for 5 minutes using a hot plate.

Example composition 71 was applied to the above-described glass with a frame-like light shielding pattern by a spin coating method to produce a coating film having a film thickness of 2.0 µm after exposure. Pre-baking was performed on the obtained coating film at 90° C. for 120 seconds, and then the coating film was exposed at an exposure amount of 200 mJ/cm² with a high-pressure mercury lamp (lamp power of 20 mW/cm²) using EVG610 (manufactured by EV Group) through a mask which could form, in the frame-like pattern, a lattice pattern with a line width of 100 µm and a line spacing of 600 µm. Puddle development was performed at 23° C. for 60 seconds using a 0.3% by mass of tetramethylammonium hydroxide (TMAH) aqueous solution. Thereafter, rinsing was performed by a spin shower using pure water. Next, a black matrix pattern was formed by heating (post-baking) at 200° C. for 5 minutes using a hot plate. The pattern had characteristics of high light shielding properties and low reflectivity, and was excellent as a light shielding pattern.

What is claimed is:

1. A composition comprising:
carbon black;
silica;
barium sulfate;
a polymerizable compound; and
a polymerization initiator.

2. The composition according to claim 1,
wherein the polymerizable compound includes a first polymerizable compound having 7 or more polymerizable groups.

3. The composition according to claim 2,
wherein the polymerizable compound includes a second polymerizable compound having 6 or less polymerizable groups, and
a mass ratio of a content of the second polymerizable compound to a content of the first polymerizable compound is 30/70 to 95/5.

4. The composition according to claim 3,
wherein all of the polymerizable groups included in the first polymerizable compound and the polymerizable groups included in the second polymerizable compound are an acryloyl group or a methacryloyl group.

5. The composition according to claim 1,
wherein the polymerization initiator includes a compound represented by Formula (1), 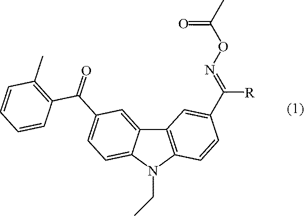
in Formula (1), R represents a group represented by Formula (1a), 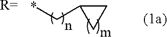
in Formula (1a), n represents an integer of 1 to 5, m represents an integer of 1 to 6, and * represents a bonding position.

6. The composition according to claim 1, further comprising:
one or more kinds of metal-containing particles selected from the group consisting of a metal nitride and a metal oxynitride.

7. The composition according to claim 1,
wherein, in a case where the composition does not include one or more kinds of metal-containing particles selected from the group consisting of a metal nitride and a metal oxynitride, a content of the carbon black is 10% to 55% by mass with respect to a total solid content of the composition, and
in a case where the composition includes one or more kinds of metal-containing particles selected from the group consisting of a metal nitride and a metal oxynitride, a total content of the carbon black and the metal-containing particles is 10% to 55% by mass with respect to the total solid content of the composition.

8. The composition according to claim 1,
wherein an average particle diameter of the silica is 3 to 200 nm.

9. The composition according to claim 1,
wherein an average particle diameter of the barium sulfate is 3 to 200 nm.

10. The composition according to claim 1, further comprising:
a silicone-based surfactant.

11. The composition according to claim 10,
wherein the silicone-based surfactant is a surfactant having a phenyl group.

12. The composition according to claim 1, further comprising:
copper phthalocyanines selected from the group consisting of copper phthalocyanine and a copper phthalocyanine derivative.

13. The composition according to claim 12,
wherein the copper phthalocyanine derivative is a salt composed of copper phthalocyanine having a sulfonic acid group and dimethyldioctadecylammonium.

14. The composition according to claim 12,
wherein a mass ratio of a content of the carbon black to a total content of the copper phthalocyanines is 4.0 to 99.

15. The composition according to claim 1,
wherein a mass ratio of a content of the carbon black to a content of the silica is 3.0 to 99.

16. The composition according to claim 1,
wherein a mass ratio of a content of the carbon black to a content of the barium sulfate is 1.5 to 99.

17. The composition according to claim 1,
wherein a mass ratio of a content of the barium sulfate to a content of the silica is 0.25 to 4.0.

18. The composition according to claim 1,
wherein a content of a solid content of the composition is 10% to 45% by mass with respect to a total mass of the composition.

19. The composition according to claim 1,
wherein the composition is a composition for forming a light shielding film.

20. A light shielding film comprising:
a cured film formed from the composition according to claim 1.

21. A solid-state imaging element comprising:
a cured film formed from the composition according to claim 1.

22. An image display device comprising:
a cured film formed from the composition according to claim 1.

23. A method for manufacturing a cured film, comprising:
a composition layer forming step of forming a composition layer using the composition according to claim 1 on a support;
an exposure step of exposing the composition layer by irradiating the composition layer with an actinic ray or a radiation; and
a development step of performing a development treatment on the composition layer after the exposure.
